(19) United States
(12) Patent Application Publication
(10) Pub. No.: US 2025/0338696 A1
(43) Pub. Date: Oct. 30, 2025

(54) CERAMIC SUBSTRATE, LIGHT-EMITTING DEVICE, AND METHODS OF MANUFACTURING CERAMIC SUBSTRATE AND LIGHT-EMITTING DEVICE

(71) Applicant: NICHIA CORPORATION, Anan-shi (JP)

(72) Inventor: Shinichi DAIKOKU, Tokushima-shi (JP)

(73) Assignee: NICHIA CORPORATION, Anan-shi (JP)

(21) Appl. No.: 19/182,589

(22) Filed: Apr. 18, 2025

(30) Foreign Application Priority Data
Apr. 26, 2024 (JP) 2024-072268

(51) Int. Cl. H10H 29/85; H01L 25/075; H10H 29/01; H10H 29/856

(52) U.S. Cl. CPC H10H 29/857; H01L 25/0753; H10H 29/0364; H10H 29/856

(57) ABSTRACT

A ceramic substrate including a ceramic plate, a seed layer arranged on an upper surface of the ceramic plate, a Cu layer arranged on an upper surface of the seed layer, an intermediate layer of one or more layers arranged on an upper surface of the Cu layer and a lateral surface of the Cu layer, and an Au layer arranged on an upper surface of the intermediate layer and a lateral surface of the intermediate layer. The upper surface of the seed layer and the intermediate layer contact each other. The upper surface of the ceramic plate and the Au layer do not contact each other. An edge portion of the upper surface of the seed layer is located outside an edge portion of a lower surface of the Cu layer in a horizontal direction.

### CROSS-REFERENCE TO RELATED APPLICATIONS

The present application claims priority under 35 U.S.C. § 119 to Japanese Patent Application No. 2024-072268, filed Apr. 26, 2024, the content of which is hereby incorporated by reference in its entirety.

### BACKGROUND

### 1. Technical Field

The present disclosure relates to a ceramic substrate, a light-emitting device, and methods of manufacturing the ceramic substrate and the light-emitting device.

### 2. Description of Related Art

In recent years, there is a need for miniaturization of microchips (semiconductor integrated circuits) to respond to the downsizing, high functionality, and integration of electronic devices and components. For example, in order to obtain finer wiring lines inside a semiconductor, a photolithography technique is used (for example, see Japanese Patent Publication No. 2023-108213).

Examples of a method of forming a wiring line by using the photolithography technique include a method in which a metal film is formed on a substrate and then, an unnecessary portion of the metal film is removed by etching to form a wiring line having a desired shape. However, in this method, the substrate may be damaged or the composition of the conductive film may change during the etching, so that a lift-off method may be used to form the wiring line (for example, see Japanese Patent Publication No. 2003-347706).

On the other hand, copper (Cu) having high conductivity is used for the wiring line. However, copper is easily corroded by moisture in the air or the like, even in a normal environment. Therefore, in a known method, a plated layer such as a nickel (Ni)-plated, a rhodium (Rh)-plated, or a gold (Au)-plated layer is formed on the copper surface (for example, see Japanese Patent No. 4706690).

### SUMMARY

Embodiments of the present disclosure can provide a ceramic substrate, a light-emitting device, and methods of manufacturing the ceramic substrate and the light-emitting device, by which, in a ceramic substrate including a Cu layer, it is possible to suppress corrosion of the Cu layer and obtain increased reliability.

A ceramic substrate according to an embodiment of the present disclosure includes a ceramic plate, a seed layer arranged on an upper surface of the ceramic plate, a Cu layer arranged on an upper surface of the seed layer, an intermediate layer of one layer or two or more layers arranged on an upper surface of the Cu layer and a lateral surface of the Cu layer, and an Au layer arranged on an upper surface of the intermediate layer and a lateral surface of the intermediate layer, in which the upper surface of the seed layer and a lower surface of the intermediate layer contact each other, the upper surface of the ceramic plate and a lower surface of the Au layer do not contact each other, and an edge portion of the upper surface of the seed layer is located outside an edge portion of a lower surface of the Cu layer in a horizontal direction.

A light-emitting device according to an embodiment of the present disclosure includes the ceramic substrate according to the embodiment of the present disclosure, and a light-emitting element arranged on the ceramic substrate.

A method of manufacturing a ceramic substrate according to an embodiment of the present disclosure includes providing a first resist layer on an upper surface of a ceramic plate, and exposing the first resist layer to light and developing the first resist layer into a predetermined shape, arranging a seed layer on the upper surface of the ceramic plate exposed from the first resist layer having been exposed to light and developed, on a lateral surface of the first resist layer, and on an upper surface of the first resist layer, providing a second resist layer to cover at least a part of an upper surface of the seed layer, and exposing the second resist layer to light and developing the second resist layer into a predetermined shape, to expose at least a part of the upper surface of the seed layer arranged on the upper surface of the ceramic plate, arranging, by electrolytic plating, a Cu layer on the upper surface of the seed layer exposed from the second resist layer having been exposed to light and developed, removing a part of the seed layer, the first resist layer, and the second resist layer, arranging an intermediate layer of one layer or two or more layers on an upper surface of the Cu layer and a lateral surface of the Cu layer, and arranging an Au layer on an upper surface of the intermediate layer and a lateral surface of the intermediate layer.

A method of manufacturing a light-emitting device according to an embodiment of the present disclosure includes preparing the ceramic substrate according to the embodiment of the present disclosure, arranging a light-emitting element on the ceramic substrate, and arranging a reflective member on an upper surface of the ceramic substrate, in which in the step pf arranging the reflective member, the reflective member is arranged to contact the Au layer and the seed layer of the ceramic substrate.

According to the embodiment of the present disclosure, it is possible to provide a ceramic substrate, a light-emitting device, and methods of manufacturing the ceramic substrate and the light-emitting element, by which, in a ceramic substrate including a Cu layer, it is possible to suppress corrosion of the Cu layer and obtain increased reliability.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic cross-sectional view illustrating an example of a ceramic substrate according to a first embodiment.

FIG. 1B is a schematic top view illustrating an example of the ceramic substrate according to the first embodiment.

FIG. 2 is a schematic cross-sectional view illustrating an example of a ceramic substrate according to a second embodiment.

FIG. 3 is a schematic cross-sectional view illustrating an example of a ceramic substrate according to a third embodiment.

FIG. 4A is a schematic top view illustrating an example of a ceramic substrate according to a fourth embodiment.

FIG. 4B is a schematic cross-sectional view in a layering direction, taken along line IVB-IVB in FIG. 4A.

FIG. 4C is an enlarged cross-sectional view of a region IVC of the ceramic substrate in FIG. 4B according to a first example of the fourth embodiment.

FIG. 4D is an enlarged cross-sectional view of the region IVC of the ceramic substrate in FIG. 4B according to a second example of the fourth embodiment.

FIG. 4E is a schematic bottom view illustrating an example of the ceramic substrate according to the fourth embodiment.

FIG. 5 is a flowchart illustrating an example of a method of manufacturing a ceramic substrate according to the first embodiment.

FIG. 6A is a schematic cross-sectional view illustrating an example of a ceramic plate used in the method of manufacturing a ceramic substrate according to the first embodiment.

FIG. 6B is a schematic cross-sectional view illustrating an example in which a first resist layer is provided on an upper surface of the ceramic plate in the method of manufacturing a ceramic substrate according to the first embodiment.

FIG. 6C is a schematic cross-sectional view illustrating an example in which the first resist layer is exposed to light and developed into a predetermined shape in the method of manufacturing a ceramic substrate according to the first embodiment.

FIG. 6D is a schematic cross-sectional view illustrating an example of arranging a seed layer in the method of manufacturing a ceramic substrate according to the first embodiment.

FIG. 6E is a schematic cross-sectional view illustrating an example in which a second resist layer is provided on the upper surface of the ceramic plate so as to cover the seed layer in the method of manufacturing a ceramic substrate according to the first embodiment.

FIG. 6F is a schematic cross-sectional view illustrating an example in which the second resist layer is exposed to light and developed into a predetermined shape in the method of manufacturing a ceramic substrate according to the first embodiment.

FIG. 6G is a schematic cross-sectional view illustrating an example of arranging a Cu layer in the method of manufacturing a ceramic substrate according to the first embodiment.

FIG. 6H is a schematic cross-sectional view illustrating an example of removing a part of the seed layer, the first resist layer, and the second resist layer in the method of manufacturing a ceramic substrate according to the first embodiment.

FIG. 6I is a schematic cross-sectional view illustrating an example of arranging an intermediate layer in the method of manufacturing a ceramic substrate according to the first embodiment.

FIG. 6J is a schematic cross-sectional view illustrating an example of arranging an Au layer in the method of manufacturing a ceramic substrate according to the first embodiment.

FIG. 7 is a flowchart illustrating an example of a method of manufacturing a ceramic substrate according to the second embodiment.

FIG. 8A is a schematic cross-sectional view illustrating an example of arranging a first intermediate layer in the method of manufacturing a ceramic substrate according to the second embodiment.

FIG. 8B is a schematic cross-sectional view illustrating an example of arranging a second intermediate layer in the method of manufacturing a ceramic substrate according to the second embodiment.

FIG. 8C is a schematic cross-sectional view illustrating an example of arranging an Au layer in the method of manufacturing a ceramic substrate according to the second embodiment.

FIG. 9 is a flowchart illustrating an example of a method of manufacturing a ceramic substrate according to a third embodiment.

FIG. 10A is a schematic cross-sectional view illustrating an example in which the first resist layer is exposed to light and developed into a predetermined shape in the method of manufacturing a ceramic substrate according to the third embodiment.

FIG. 10B is an enlarged cross-sectional view of a region XB in FIG. 10A.

FIG. 10C is a schematic cross-sectional view illustrating an example of arranging a seed layer in the method of manufacturing a ceramic substrate according to the third embodiment.

FIG. 10D is a schematic cross-sectional view illustrating an example of providing a second resist layer in the method of manufacturing a ceramic substrate according to the third embodiment.

FIG. 10E is a schematic cross-sectional view illustrating an example in which the second resist layer is exposed to light and developed into a predetermined shape in the method of manufacturing a ceramic substrate according to the third embodiment.

FIG. 10F is a schematic cross-sectional view illustrating an example of arranging a Cu layer in the method of manufacturing a ceramic substrate according to the third embodiment.

FIG. 10G is a schematic cross-sectional view illustrating an example of removing a part of the seed layer, the first resist layer, and the second resist layer in the method of manufacturing a ceramic substrate according to the third embodiment.

FIG. 10H is a schematic cross-sectional view illustrating an example of arranging an intermediate layer in the method of manufacturing a ceramic substrate according to the third embodiment.

FIG. 10I is a schematic cross-sectional view illustrating an example of arranging an Au layer in the method of manufacturing a ceramic substrate according to the third embodiment.

FIG. 11 is a flowchart illustrating an example of a method of manufacturing a ceramic substrate according to a fourth embodiment.

FIG. 12A is a schematic cross-sectional view illustrating an example in which the first resist layer is exposed to light and developed into a predetermined shape in the method of manufacturing a ceramic substrate according to the fourth embodiment.

FIG. 12B is an enlarged cross-sectional view of a region XIIB in FIG. 12A.

FIG. 12C is a schematic cross-sectional view illustrating an example of arranging a seed layer in the method of manufacturing a ceramic substrate according to the fourth embodiment.

FIG. 12D is a schematic cross-sectional view illustrating an example of providing a second resist layer in the method of manufacturing a ceramic substrate according to the fourth embodiment.

FIG. 12E is a schematic cross-sectional view illustrating an example in which the second resist layer is exposed to light and developed into a predetermined shape in the method of manufacturing a ceramic substrate according to the fourth embodiment.

FIG. 12F is a schematic cross-sectional view illustrating an example of arranging a Cu layer in the method of manufacturing a ceramic substrate according to the fourth embodiment.

FIG. 12G is a schematic cross-sectional view illustrating an example of removing a part of the seed layer, the first resist layer, and the second resist layer in the method of manufacturing a ceramic substrate according to the fourth embodiment.

FIG. 12H is a schematic cross-sectional view illustrating an example of arranging an intermediate layer in the method of manufacturing a ceramic substrate according to the fourth embodiment.

FIG. 12I is a schematic cross-sectional view illustrating an example of arranging an Au layer in the method of manufacturing a ceramic substrate according to the fourth embodiment.

FIG. 13A is a schematic top view illustrating an example of a light-emitting device according to an embodiment.

FIG. 13B is a schematic cross-sectional view in a layering direction, taken along line XIIIB-XIIIB in FIG. 13A.

FIG. 13C is an enlarged cross-sectional view of a region XIIIC in FIG. 13B.

FIG. 13D is an enlarged cross-sectional view of a region XIIID in FIG. 13C.

FIG. 14 is a flowchart illustrating an example of a method of manufacturing a light-emitting device according to the embodiment.

FIG. 15A is an SEM image of an intermediate of a ceramic substrate in a plan view in a horizontal direction obtained by arranging a Cu layer in the method of manufacturing a ceramic substrate according to the fourth embodiment, and observed from above at a magnification of 50 times.

FIG. 15B is an enlarged image of a cross section of a region XVB in FIG. 15A in a thickness direction, and is an SEM image of a cross section of an intermediate of a ceramic substrate obtained by arranging a Cu layer in the method of manufacturing a ceramic substrate according to the fourth embodiment, and observed at a magnification of 10000 times.

### DETAILED DESCRIPTION OF EMBODIMENT

A ceramic substrate, a light-emitting device, and manufacturing methods of the ceramic substrate and the light-emitting device according to an embodiment of the present disclosure will be described in detail with reference to the drawings. However, the embodiments described below are examples of a ceramic substrate, a light-emitting device, and manufacturing methods of the ceramic substrate and the light-emitting device for embodying the technical idea of the present disclosure, and the present disclosure is not limited to the embodiments described below.

Furthermore, dimensions, materials, shapes, relative arrangements, and the like of constituent members described in the embodiments are not intended to limit the scope of the present disclosure thereto, unless otherwise specified, and are merely exemplary. Note that the sizes, positional relationships, and the like of members illustrated in each of the drawings may be exaggerated for clarity of description. In the following description, members having the same terms and reference characters represent the same members or members of the same quality, and a detailed description of these members will be omitted as appropriate. Furthermore, in order to avoid excessive complexity in the drawings, schematic views that omit some elements may be used, or end views that illustrate only cut surfaces may be used as cross-sectional views.

In the present disclosure, polygons such as rectangles, triangles, and quadrangles, including shapes in which the corners of the polygon are rounded, chamfered, beveled, coved, and the like, are referred to as polygons. A shape obtained by processing not only the corners (ends of a side) but also an intermediate portion of the side is also referred to as a polygon. That is, a shape that is partially processed while leaving the polygon as the base is included in the interpretation of the “polygon” described in the present disclosure.

The same applies not only to polygons, but also to terms expressing a specific shape such as a trapezoid, a circle, and a shape including protrusions and recessions. Furthermore, the same applies when referring to each side forming such a shape. That is, even if processing is performed on a corner or an intermediate portion of a certain side, the interpretation of “side” includes the processed portion. When a “polygon” or a “side” not partially processed is to be distinguished from a processed shape, “strict” will be added to the description as in, for example, “strict quadrangle”.

Note that, in the following description, terms indicating a specific direction or position (for example, “upper”, “lower”, “horizontal”, “upper surface”, “lower surface”, “lateral surface”, “X”, “Y”, “Z”, and other terms including these terms) are used as necessary. However, these terms are used to facilitate understanding of the invention with reference to the drawings, and the technical scope of the present invention is not excessively limited by the meaning of these terms. For example, when the term “upper surface” is used, the invention does not always have to be used so as to face upward. In the embodiments, the expression “covering” includes not only a case of covering by direct contact but also a case of indirectly covering, for example, via another member.

In the present specification or the claims, when a plurality of constituent components are provided and these constituent components are to be denoted individually, the constituent components may be distinguished by adding terms such as “first”, “second”, and the like in front of the terms of the constituent components.

### Ceramic Substrate

### First Embodiment

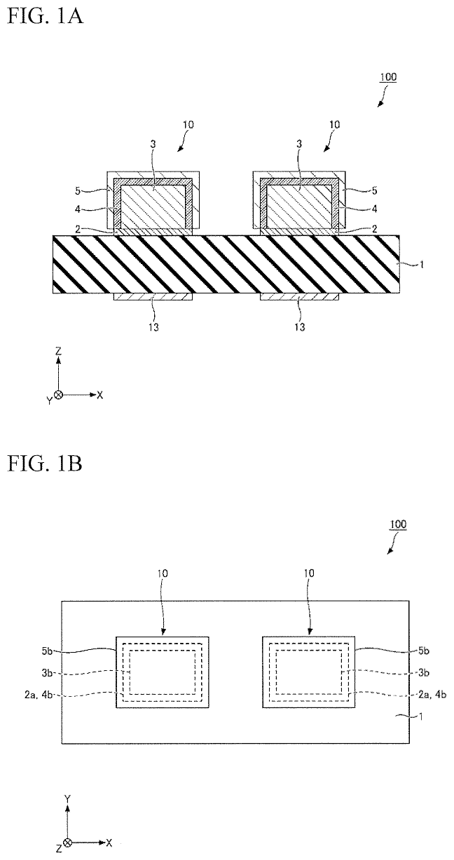

FIG. 1A is a schematic cross-sectional view illustrating an example of a ceramic substrate according to a first embodiment. FIG. 1B is a schematic top view illustrating an example of the ceramic substrate according to the first embodiment. Components of a ceramic substrate 100 are described below.

The ceramic substrate 100 according to the first embodiment includes a ceramic plate 1, a seed layer 2 arranged on an upper surface of the ceramic plate 1, a Cu layer 3 arranged on an upper surface of the seed layer 2, an intermediate layer 4 of one layer arranged on an upper surface of the Cu layer 3 and a lateral surface of the Cu layer 3, and an Au layer 5 arranged on an upper surface of the intermediate layer 4 and a lateral surface of the intermediate layer 4. The upper surface of the seed layer 2 and a lower surface of the intermediate layer 4 contact each other. The upper surface of the ceramic plate 1 and a lower surface of the Au layer 5 do not contact each other. An edge portion 2a of the upper surface of the seed layer 2 is located outside an edge portion 3b of a lower surface of the Cu layer 3 in a horizontal direction. The ceramic substrate 100 according to the first embodiment can further include other configurations, as necessary.

A layering direction in which the ceramic plate 1, the seed layer 2, the Cu layer 3, the intermediate layer 4, and the Au layer 5 are layered is a Z-axis direction. The X-axis is an axis perpendicular to the Z-axis direction, which is the layering direction. The Y-axis is an axis perpendicular to the X-axis direction and perpendicular to the Z-axis direction, which is the layering direction. The X-axis, the Y-axis, and the Z-axis are orthogonal to each other. It is only required that the horizontal direction of the ceramic plate 1 is a direction perpendicular to the Z-axis direction, which is the layering direction, and the horizontal direction can be the X-axis direction or the Y-axis direction. In the present specification, the X-Y plane is a horizontal plane of the ceramic substrate 100, and both the X-axis direction and the Y-axis direction are horizontal directions of the ceramic substrate 100.

In the ceramic substrate 100, a region in which the seed layer 2, the Cu layer 3, the intermediate layer 4, and the Au layer 5 are layered is referred to as a region 10. That is, on the upper surface of the ceramic substrate 100, the upper surface of the ceramic plate 1 is exposed in a region other than the region 10. When the ceramic substrate 100 is used in a light-emitting device, a light-emitting element is suitably arranged in the region 10.

A shape of the region 10 in a plan view in the ceramic substrate 100 is not particularly limited. However, when the ceramic substrate 100 is used in a light-emitting device, the region 10 preferably has a shape corresponding to the shape of an electrode, the layout, and the like of the light-emitting element.

### Ceramic Plate 1

The ceramic plate 1 is an insulating member serving as a base on which the seed layer 2, the Cu layer 3, the intermediate layer 4, and the Au layer 5 are arranged. The ceramic plate 1 is sintered, and is preferably not in a softened state before sintering.

The shape of the ceramic plate 1 in a plan view in the horizontal direction is not particularly limited. For example, the shape of the ceramic plate 1 can be any of various shapes including a circle, an ellipse, a polygon such as a quadrangle or a hexagon, a polygon with rounded corners, and a shape obtained by combining these shapes. Among these shapes, a quadrangle is preferable, and a rectangle is more preferable. The shape of the ceramic plate 1 in a plan view and the dimensions of the ceramic plate 1 can be appropriately adjusted depending on the required performance such as the dimensions and numbers of the Cu layer 3 and the like to be arranged on the ceramic plate 1.

The upper surface of the ceramic plate 1 may be a flat surface or may not be a flat surface. However, when the ceramic substrate 100 is used in a light-emitting device, the upper surface is preferably a flat surface because a light-emitting element can be suitably arranged on the ceramic plate 1.

The lower surface of the ceramic plate 1 is a surface on the opposite side to the upper surface on which the Cu layer 3 and the like are arranged in the ceramic plate 1. The lower surface of the ceramic plate 1 may be a flat surface or may not be a flat surface. However, when the ceramic substrate 100 is used in a light-emitting device, the lower surface is preferably a flat surface because the ceramic substrate 100 can be suitably arranged on a mounting substrate.

For example, the upper surface and the lower surface of the ceramic plate 1 are parallel. Here, when the surfaces of the ceramic plate 1 are described as being “parallel”, an allowable difference is within ±5 degrees.

The material of the ceramic plate 1 is not particularly limited, as long as the material is an insulating material. However, when the ceramic substrate 100 is used in a light-emitting device, it is preferable to use a material that does not easily transmit light from a light-emitting element and light from the outside. Examples of the material of the ceramic plate 1 include nitride-based ceramics such as aluminum nitride, silicon nitride, and boron nitride; oxide-based ceramics such as aluminum oxide, silicon oxide, calcium oxide, and magnesium oxide; silicon carbide; mullite; and borosilicate glass. These materials can be used alone or in combination of two or more types.

The ceramic plate 1 preferably contains these insulating materials as a main material, and can further contain other sub-materials as necessary. Here, the term “main material” refers to a material having the largest substance amount among the materials constituting the ceramic plate 1.

A sub-material in the ceramic plate 1 is not particularly limited, and examples thereof include glass.

An average thickness of the ceramic plate 1 is not particularly limited, but is preferably in a range from 100 μm to 1000 μm, and more preferably in a range from 120 μm to 500 μm.

The average thickness of the ceramic plate 1 is a value obtained by measuring the thickness at two locations freely selected from corner portions of the ceramic plate 1 and calculating an average of the thickness at the two locations. The thickness of the corner portions of the ceramic plate 1 is measured by using a macro gauge.

### Seed Layer 2

The seed layer 2 is arranged on the upper surface of the ceramic plate 1.

In the seed layer 2, the edge portion 2a of the upper surface of the seed layer 2 is located outside the edge portion 3b of the lower surface of the Cu layer 3 in a horizontal direction. In the horizontal direction, the edge portion 2a of the upper surface of the seed layer 2 is preferably arranged outside in a range from 1 μm to 5 μm, and more preferably in a range from 1.2 μm to 3 μm from the edge portion 3b of the lower surface of the Cu layer 3. An inner region surrounded by the edge portion 3b of the lower surface of the Cu layer 3 is defined as the inside of the edge portion 3b of the lower surface of the Cu layer 3. An outer region surrounded by the edge portion 3b of the lower surface of the Cu layer 3 is defined as the outside of the edge portion 3b of the lower surface of the Cu layer 3. When the edge portion 2a of the upper surface of the seed layer 2 is located outside the edge portion 3b of the lower surface of the Cu layer 3 in the horizontal direction, corrosion of the lower surface of the Cu layer 3 can be suppressed, and the ceramic substrate 100 having increased reliability can be obtained.

In the seed layer 2, the edge portion 2a of the upper surface of the seed layer 2 is preferably located inside an edge portion 5b of the lower surface of the Au layer 5 in the horizontal direction. Specifically, in the horizontal direction, the edge portion 2a of the upper surface of the seed layer 2 is preferably arranged inside in a range from 1.0 μm to 5.0 μm, and more preferably in a range from 1.2 μm to 3 μm from the edge portion 5b of the lower surface of the Au layer 5. An inner region surrounded by the edge portion 5b of the lower surface of the Au layer 5 is defined as the inside of the edge portion 5b of the lower surface of the Au layer 5. An outer region surrounded by the edge portion 5b of the lower surface of the Au layer 5 is defined as the outside of the edge portion 5b of the lower surface of the Au layer 5. When the edge portion 2a of the upper surface of the seed layer 2 is located inside the edge portion 5b of the lower surface of the Au layer 5 in the horizontal direction, corrosion of the lower surface of the Cu layer 3 can be suitably suppressed, and the ceramic substrate 100 having further increased reliability can be obtained.

Furthermore, a lateral surface of the seed layer 2 is preferably exposed from the Au layer 5. The lateral surface of the seed layer 2 is a surface connecting the upper surface and the lower surface of the seed layer 2 in a cross-sectional view of the ceramic substrate 100.

In the ceramic substrate 100 according to the first embodiment, the entire lower surface of the intermediate layer 4 contacts the upper surface of the seed layer 2. Thus, the edge portion 2a of the upper surface of the seed layer 2 and an edge portion 4b of the lower surface of the intermediate layer 4 coincide with each other in the horizontal direction in a plan view. However, the arrangement of these edge portions 2a and 4b is not limited thereto.

For example, only a part of the lower surface of the intermediate layer 4 may contact the upper surface of the seed layer 2, and the other part of the lower surface of the intermediate layer 4 may not contact the upper surface of the seed layer 2, but the other part of the lower surface of the intermediate layer 4 is covered with the Au layer 5. In this case, the edge portion 2a of the upper surface of the seed layer 2 is arranged inside the edge portion 4b of the lower surface of the intermediate layer 4 in the horizontal direction in a plan view. That is, the edge portion 2a of the upper surface of the seed layer 2 is arranged outside the edge portion 3b of the lower surface of the Cu layer 3 and inside the edge portion 4b of the lower surface of the intermediate layer 4. An inner region surrounded by the edge portion 4b of the lower surface of the intermediate layer 4 is defined as the inside of the edge portion 4b of the lower surface of the intermediate layer 4, and an outer region surrounded by the edge portion 4b of the lower surface of the intermediate layer 4 is defined as the outside of the edge portion 4b of the lower surface of the intermediate layer 4.

For example, the entire lower surface of the intermediate layer 4 and the entire lower surface of the Au layer 5 may contact the upper surface of the seed layer 2. In this case, the edge portion 2a of the upper surface of the seed layer 2 and the edge portion 5b of the lower surface of the Au layer 5 coincide with each other, or the edge portion 2a of the upper surface of the seed layer 2 is located outside the edge portion 5b of the lower surface of the Au layer 5, in the horizontal direction in a plan view.

For example, as long as the entire lower surface of the intermediate layer 4 and a part of the lower surface of the Au layer 5 contact the upper surface of the seed layer 2, the other part of the lower surface of the Au layer 5 may not contact the upper surface of the seed layer 2. In this case, the edge portion 2a of the upper surface of the seed layer 2 is arranged outside the edge portion 4b of the lower surface of the intermediate layer 4 and inside the edge portion 5b of the lower surface of the Au layer 5, in the horizontal direction in a plan view. That is, the edge portion 2a of the upper surface of the seed layer 2 is arranged outside the edge portion 3b of the lower surface of the Cu layer 3, outside the edge portion 4b of the lower surface of the intermediate layer 4, and inside the edge portion 4b of the lower surface of the intermediate layer 4.

The shape of the seed layer 2 in a plan view and the dimensions of the seed layer 2 in the horizontal direction are not particularly limited, as long as the edge portion 2a of the upper surface of the seed layer 2 is located outside the edge portion 3b of the lower surface of the Cu layer 3. When the ceramic substrate 100 is used in a light-emitting device, the shape and the dimensions of the seed layer 2 can be appropriately adjusted depending on the shape, the dimensions, the number, and the like of the light-emitting elements arranged in the region 10.

The material of the seed layer 2 is not particularly limited, but is preferably a conductive material. Examples of the material include Ti, Cu, Au, Ru, TiNi, TiW, CuNi, and NiCr. These materials can be used alone or in combination of two or more types. Among these materials, the seed layer 2 is preferably made up of one or more types of layers selected from the group consisting of a Ti layer, a Cu layer, an Au layer, a Ru layer, a TiNi layer, a TiW layer, a CuNi layer, and a NiCr layer, and more preferably any one layer or a combination of layers selected from the group consisting of a combination of Ti layer and Cu layer, a combination of Ti layer and Au layer, a combination of Ti layer and TiNi layer, a combination of Ti layer and TiW layer, a combination of Ti layer, TiW layer, and Cu layer, a combination of Ti layer, Ru layer, and Cu layer, a TiW layer, a CuNi layer, and a NiCr layer. These materials are used as the material of the seed layer 2, so that the adhesion with the Cu layer 3 is increased, and thus, corrosion of the Cu layer 3 can be suppressed, and the reliability can be improved.

An average thickness of the seed layer 2 is not particularly limited, but is preferably in a range from 0.1 μm to 2.0 μm, and more preferably in a range from 0.3 μm to 1 μm. When the average thickness of the seed layer 2 is in a range from 0.1 μm to 2.0 μm, it is possible to prevent the lower surface of the intermediate layer 4 and the lower surface of the Au layer 5 from contacting the ceramic plate 1. Therefore, no gap is formed in the periphery of the Cu layer 3, corrosion of the Cu layer 3 can be suppressed, and the ceramic substrate 100 having increased reliability can be obtained.

The average thickness of the seed layer 2 is obtained as follows. A scanning electron microscope (SEM) is used to capture an image of a cross section of a region including the seed layer 2 of the ceramic substrate 100 in the Z-axis direction. The thickness of the seed layer 2 is measured at three locations (for example, one location at a center portion and two locations at end portions) freely selected in the field of view of the SEM image, and the average thickness at the three locations is calculated.

### Cu Layer 3

The Cu layer 3 is arranged on the upper surface of the seed layer 2. The lower surface of the Cu layer 3 is covered by the seed layer 2, and the lateral surface and the upper surface of the Cu layer 3 are covered by the intermediate layer 4. The upper surface of the seed layer 2 and the intermediate layer 4 contact each other, and thus, the entire surface of the Cu layer 3 is covered by the seed layer 2 and the intermediate layer 4. Therefore, the Cu layer 3 is not affected by an external environment such as air, corrosion can be suppressed, and the ceramic substrate 100 having increased reliability can be obtained.

The shape of the Cu layer 3 in the horizontal direction in a plan view is not particularly limited. For example, the shape of the Cu layer 3 can be any of various shapes including a circle, an ellipse, a polygon such as a quadrangle and a hexagon, a polygon with rounded corners, and a shape obtained by combining these shapes. When the ceramic substrate 100 is used in a light-emitting device, the shape of the Cu layer 3 in a plan view and the dimensions of the Cu layer 3 can be appropriately adjusted depending on the shape, the dimensions, the number, and the like of the light-emitting elements arranged in the region 10.

An average thickness of the Cu layer 3 is not particularly limited, but is preferably in a range from 10 μm to 60 μm, and more preferably in a range from 15 μm to 30 μm.

The average thickness of the Cu layer 3 is obtained as follows. A scanning electron microscope (SEM) is used to capture an image of a cross section of a region including the Cu layer 3 of the ceramic substrate 100 in the Z-axis direction. The thickness of the Cu layer 3 is measured at three locations (for example, one location at a center portion, and two locations at end portions) freely selected in the field of view of the SEM image, and the average thickness at the three locations is calculated.

### Intermediate Layer 4

The intermediate layer 4 is arranged on the upper surface of the Cu layer 3 and the lateral surface of the Cu layer 3. In the ceramic substrate 100 according to the first embodiment, the intermediate layer 4 is a single layer. The upper surface of the seed layer 2 and the intermediate layer 4 contact each other. The intermediate layer 4 can improve the adhesion between the Cu layer 3 and the Au layer 5.

The shape and the dimensions of the intermediate layer 4 in a plan view in the horizontal direction can be appropriately adjusted in accordance with the shape of the Cu layer 3 in a plan view and its dimensions.

The material of the intermediate layer 4 is not particularly limited, but is preferably a conductive material. Examples of the material include Ti, Ni, Pd, Pt, Rh, W, and Ru. These materials can be used alone or in combination of two or more types. Among these materials, the material of the intermediate layer 4 preferably contains Ni or Pd. When the intermediate layer 4 is formed by electroless plating, the material is preferably Ni, NiP, NiB, Pd, or the like.

An average thickness of the intermediate layer 4 is not particularly limited, but is preferably in a range from 0.03 μm to 1 μm, and more preferably in a range from 0.05 μm to 0.1 μm.

The average thickness of the intermediate layer 4 is obtained as follows. A scanning electron microscope (SEM) is used to capture an image of a cross section of a region including the intermediate layer 4 of the ceramic substrate 100 in the Z-axis direction. The thickness of the intermediate layer 4 is measured at three locations (for example, one location at a center portion, and two locations at end portions) freely selected in the field of view of the SEM image, and the average thickness at the three locations is calculated.

### Au Layer 5

The Au layer 5 is arranged on the upper surface of the intermediate layer 4 and the lateral surface of the intermediate layer 4. The upper surface of the ceramic plate 1 and the Au layer 5 do not contact each other. The Au layer 5 is the outermost layer in the region 10.

The Au layer 5 is used as the outermost surface of the region 10, so that the connection reliability with a light-emitting element is improved when the ceramic substrate 100 is used in a light-emitting device. Generally, gold is frequently used in an electrode of a light-emitting element. Therefore, the connection between the Au layer 5 in the region 10 and Au used in the electrode of the light-emitting element is highly reliable, so that the connection does not deteriorate, even when a high voltage is applied, and the highly reliable connection can be maintained over a long period of time.

The shape of the Au layer 5 in a plan view in the horizontal direction and its dimensions can be appropriately adjusted in accordance with the shapes of the Cu layer 3 and the intermediate layer 4 in a plan view and their dimensions.

An average thickness of the Au layer 5 is not particularly limited, but is preferably in a range from 0.03 μm to 1 μm, and more preferably in a range from 0.05 μm to 0.1 μm.

The average thickness of the Au layer 5 is obtained as follows. A scanning electron microscope (SEM) is used to capture an image of a cross section of a region including the Au layer 5 of the ceramic substrate 100 in the Z-axis direction. The thickness of the Au layer 5 is measured at three locations (for example, one location at a center portion, and two locations at end portions) freely selected in the field of view of the SEM image, and the average thickness at the three locations is calculated.

### Other Configurations

Examples of other configurations in the ceramic substrate 100 include a heat dissipation member and a wiring portion that is different from the region 10 and from a pad portion 11 described later.

When the ceramic substrate 100 is used in a light-emitting device, the ceramic substrate 100 can further include, between a plurality of the regions 10, a wiring portion used for an electric connection with a light-emitting element, in accordance with the number of light-emitting elements to be mounted. For example, one wiring portion or a plurality of wiring portions for relay can be arrayed between a pair of the regions 10. The wiring portion arranged between the pair of regions 10 can have a shape and an arrangement such that a plurality of light-emitting elements are driven independently, or such that the light-emitting elements are driven in series, in parallel, or in a combination thereof, depending on the shape of the pair of regions 10, the power supply control thereof, and the like.

The ceramic substrate 100 can include a heat dissipation member on the lower surface of the ceramic plate 1. In a plan view in the horizontal direction, the heat dissipation member is preferably provided so as to overlap a region immediately below the region 10 in which each of the light-emitting elements is arranged. The shape of the heat dissipation member preferably has a large area in a plan view. The shape, the structure, and the dimensions of the heat dissipation member are not particularly limited and can be appropriately selected according to a purpose. The material of the heat dissipation member can be a metal material similar to the one used in the region 10.

### Second Embodiment

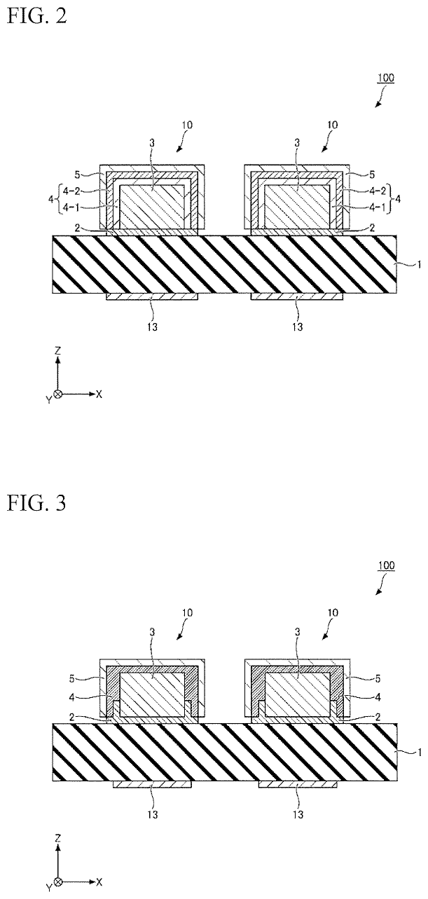

FIG. 2 is a schematic cross-sectional view illustrating an example of a ceramic substrate according to a second embodiment. The ceramic substrate 100 according to the second embodiment has the same configuration as that of the ceramic substrate 100 according to the first embodiment, except that the intermediate layer 4 is made up of two layers including a first intermediate layer 4-1 and a second intermediate layer 4-2.

The first intermediate layer 4-1 and the second intermediate layer 4-2 are made of different materials. The material of the first intermediate layer 4-1 is preferably Ni. The material of the second intermediate layer 4-2 is preferably Pd.

In the ceramic substrate 100 according to the second embodiment, a Ni layer serving as the first intermediate layer 4-1 is arranged on the upper surface of the Cu layer 3 and the lateral surface of the Cu layer 3, a Pd layer serving as the second intermediate layer 4-2 is arranged on the upper surface of the Ni layer serving as the first intermediate layer 4-1 and the lateral surface of the Ni layer serving as the first intermediate layer 4-1, and the Au layer 5 is arranged on the upper surface of the Pd layer serving as the second intermediate layer 4-2 and the lateral surface of the Pd layer serving as the second intermediate layer 4-2.

Here, the entire lower surface of the first intermediate layer 4-1 and the entire lower surface of the second intermediate layer 4-2 both contact the upper surface of the seed layer 2, but the first intermediate layer 4-1 and the second intermediate layer 4-2 are not limited thereto. For example, only the entire lower surface of the first intermediate layer 4-1 may contact the upper surface of the seed layer 2, and the lower surface of the second intermediate layer 4-2 may not contact the upper surface of the seed layer 2. The entire lower surface of the first intermediate layer 4-1 and a part of the lower surface of the second intermediate layer 4-2 may contact the upper surface of the seed layer 2. Only a part of the lower surface of the first intermediate layer 4-1 may contact the upper surface of the seed layer 2, and the other part of the lower surface of the first intermediate layer 4-1 and the entire lower surface of the second intermediate layer 4-2 may not contact the upper surface of the seed layer 2.

In the ceramic substrate 100 according to the second embodiment, a case in which the intermediate layer 4 includes two layers is described. However, in the ceramic substrate 100 according to an embodiment of the present disclosure, the intermediate layer 4 can include three or more layers. The material of the intermediate layers 4 in the case of three or more layers is not particularly limited and can be appropriately selected according to a purpose.

### Third Embodiment

FIG. 3 is a schematic cross-sectional view illustrating an example of a ceramic substrate according to a third embodiment. The ceramic substrate 100 according to the third embodiment has the same configuration as that of the ceramic substrate 100 according to the first embodiment, except that the shape of the seed layer 2 in a cross-sectional view is different.

In the ceramic substrate 100 according to the third embodiment, the seed layer 2 is continuous from the lower surface of the Cu layer 3 to a part of the lateral surface of the Cu layer 3, and the intermediate layer 4 is arranged so as to cover the seed layer 2 arranged on the part of the lateral surface of the Cu layer 3.

Here, the seed layer 2 being “continuous” means that the seed layer 2 is arranged without interruption not only in the horizontal direction of the X-Y plane, but also in the Z-axis direction which is the layering direction. Thus, compared with the ceramic substrate 100 according to the first embodiment, a boundary between the lower surface of the intermediate layer 4 and the upper surface of the seed layer 2 is not formed on the lower surface of the Cu layer 3, it is possible to more reliably prevent contact between the Cu layer 3 and the external environment such as air, corrosion can be further suppressed, and the ceramic substrate 100 having further increased reliability can be obtained.

### Fourth Embodiment

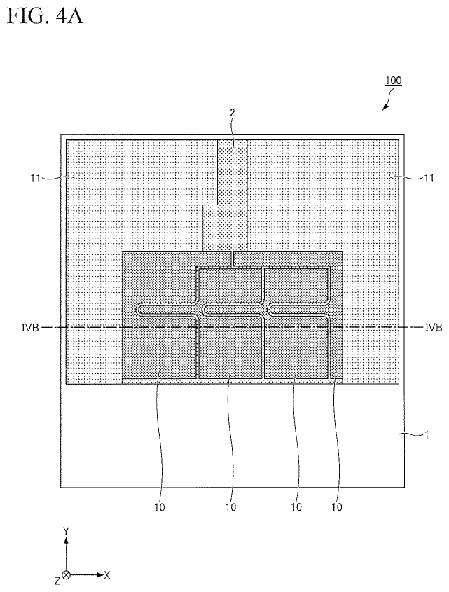

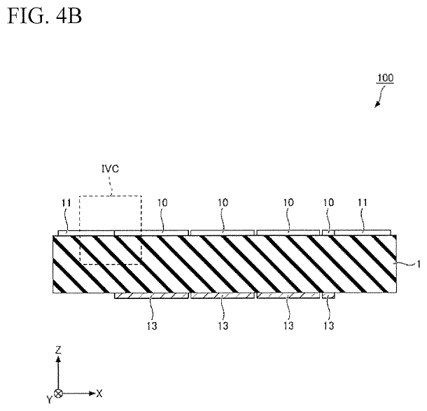

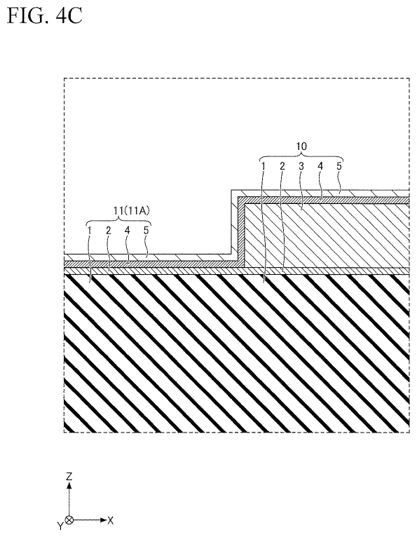

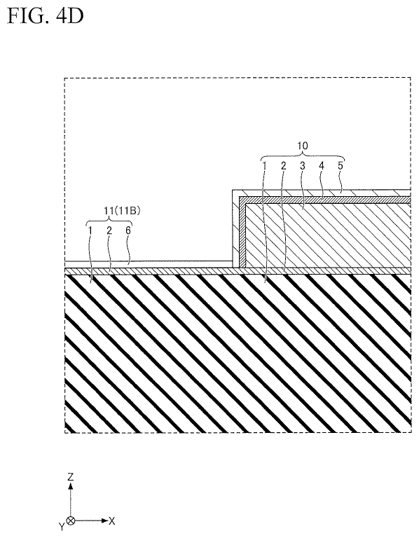

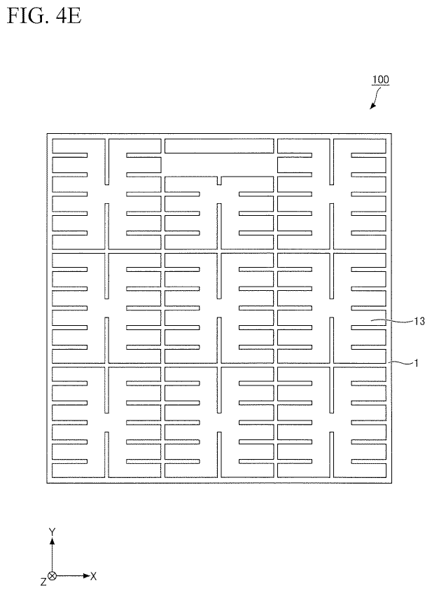

FIG. 4A is a schematic top view illustrating an example of a ceramic substrate according to a fourth embodiment. The ceramic substrate 100 according to the fourth embodiment has the same configuration as that of the ceramic substrate 100 according to the first embodiment, except that the ceramic substrate 100 according to the fourth embodiment further includes the pad portion 11 that is electrically connected to the Au layer 5.

### Pad Portion 11

A layer configuration of the pad portion 11 is not particularly limited and can be appropriately selected according to a purpose, as long as the pad portion 11 can be electrically connected to the Au layer 5 in the region 10. A pad portion 11A of the ceramic substrate 100 according to a first example of the fourth embodiment and a pad portion 11B of the ceramic substrate 100 according to a second example of the fourth embodiment will be described below as examples of the pad portion 11. On one ceramic substrate 100, only one of the pad portion 11A and the pad portion 11B can be provided, or the region can be divided into separate regions to simultaneously provide both of the pad portion 11A and the pad portion 11B.

The shape of the pad portion 11 in a plan view in the horizontal direction is not particularly limited. However, the pad portion 11 preferably extends from the region 10 to the vicinity of the end portion of the ceramic substrate 100. In a case in which the ceramic substrate 100 is used in a light-emitting device, the total planar area of the region 10 and the pad portion 11 is increased, so that the light-emitting device can pass a current easily and have low electric resistance. Here, the expression “the vicinity of the end portion of the ceramic substrate 100” refers to a case in which the distance from an outer edge of the ceramic plate 1 on the surface, on which the region 10 and the pad portion 11 are arranged, to the region 10 or the pad portion 11 is in a range from 0.01 mm to 0.5 mm.

Furthermore, the region 10 and the pad portion 11 are arranged in the vicinity of the end portion of the ceramic substrate 100, and thus, a connection length of a power supply member such as a wire used for supplying power to an external connection portion can be reduced, and power can be reliably and easily supplied. Among these configurations, in the ceramic substrate 100 having a substantially rectangular shape in a plan view in the horizontal direction, the pad portion 11 preferably has such a shape in a plan view in the horizontal direction that a pair of positive and negative external connection portions each extend toward one side of the rectangular shape. Thus, a power supply member supplying power from the outside can be connected from the same direction with substantially the same length in both the positive and negative external connection portions.

### First Example of Fourth Embodiment

FIG. 4B is a schematic cross-sectional view in a layering direction, taken along line IVB-IVB in FIG. 4A. FIG. 4C is an enlarged cross-sectional view of a region IVC in FIG. 4B of a ceramic substrate according to a first example of the fourth embodiment.

The pad portion 11A in the ceramic substrate 100 according to the first example of the fourth embodiment includes the ceramic plate 1, the seed layer 2 arranged on the upper surface of the ceramic plate 1, the intermediate layer 4 arranged on the upper surface of the seed layer 2, and the Au layer 5 arranged on the upper surface of the intermediate layer 4. Preferably, the pad portion 11A does not include the Cu layer 3. Thus, the thickness of the pad portion 11A can be reduced. When the ceramic substrate 100 is used in a light-emitting device, the Cu layer 3 may only be arranged in the region 10 in which a light-emitting element is arranged, to improve the heat dissipation of the light-emitting element.

### Second Example of Fourth Embodiment

FIG. 4D is an enlarged cross-sectional view of the region IVC in FIG. 4B of a ceramic substrate according to a second example of the fourth embodiment.

The pad portion 11B in the ceramic substrate 100 according to the second example of the fourth embodiment includes the ceramic plate 1, the seed layer 2 arranged on the upper surface of the ceramic plate 1, and an Al layer 6 arranged on the upper surface of the seed layer 2. Preferably, the pad portion 11B does not include the Cu layer 3. Thus, the thickness of the pad portion 11B can be reduced. When the ceramic substrate 100 is used in a light-emitting device, the Cu layer 3 may only be arranged in the region 10 in which a light-emitting element is arranged, to improve the heat dissipation of the light-emitting element. When Al is used in a wire, the wire can be made of the same material as the surface of the pad portion 11B, and breakage or disconnection between the wire and the pad portion 11B can be prevented.

### Heat Dissipation Member 13

FIG. 4E is a schematic bottom view illustrating an example of the ceramic substrate according to the fourth embodiment. For example, the heat dissipation member 13 can have a shape obtained by combining a plurality of shapes formed by cutting a rectangular pattern into a comb shape.

### Method of Manufacturing Ceramic Substrate

### First Embodiment

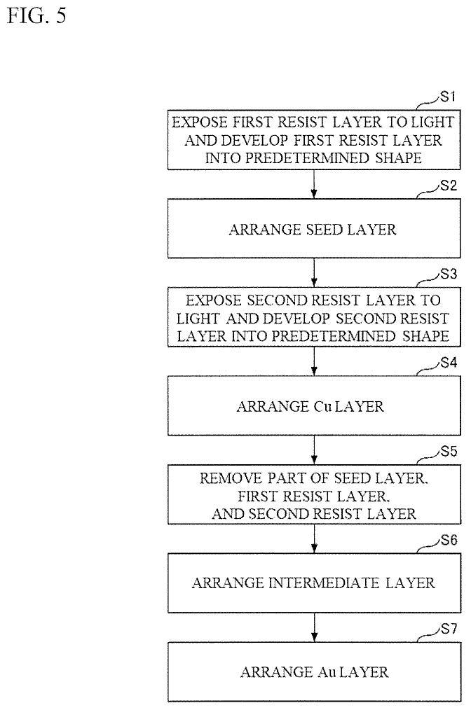

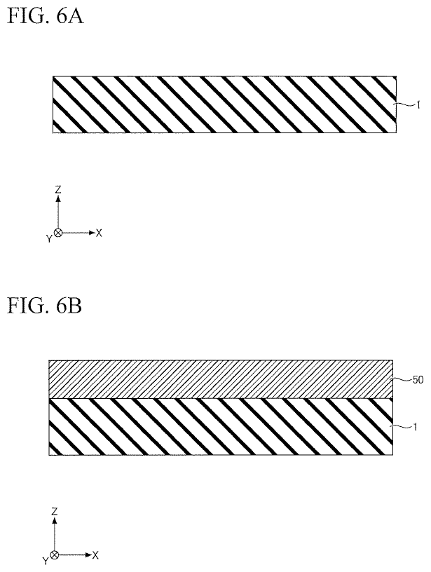

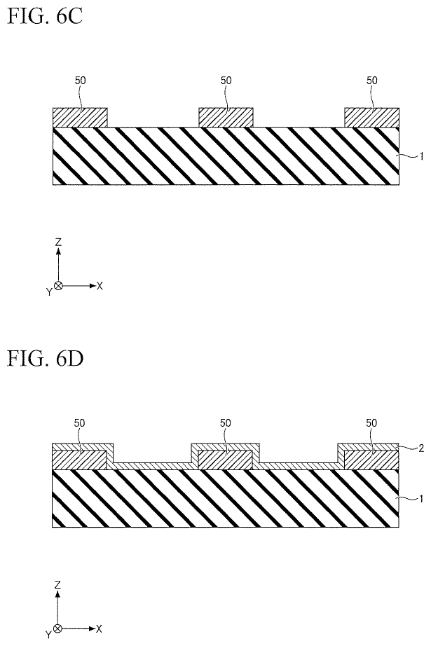

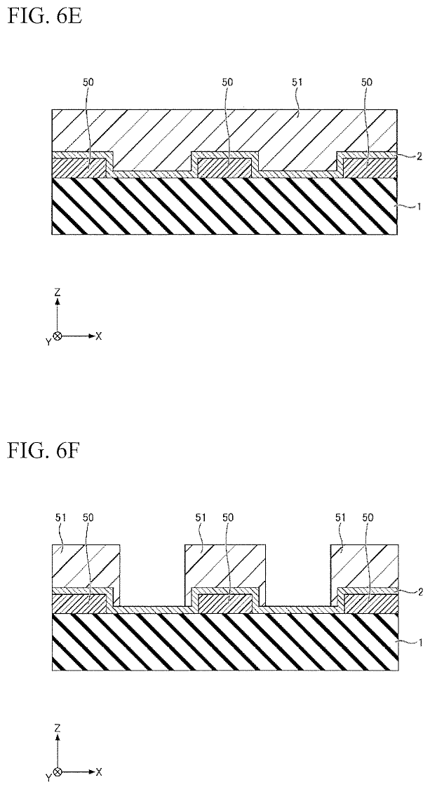

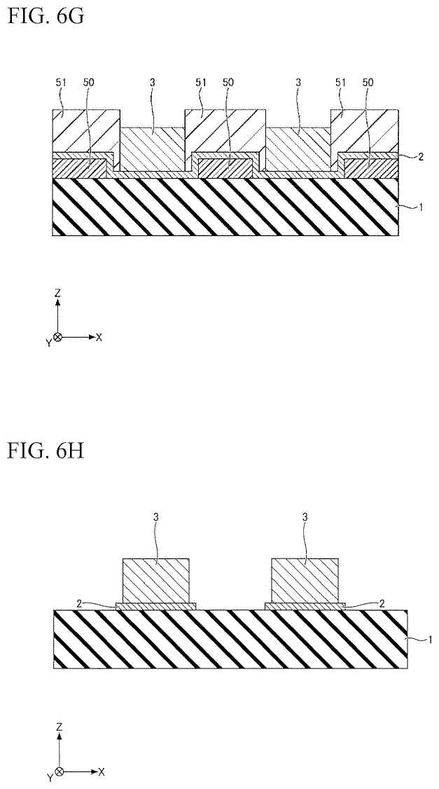

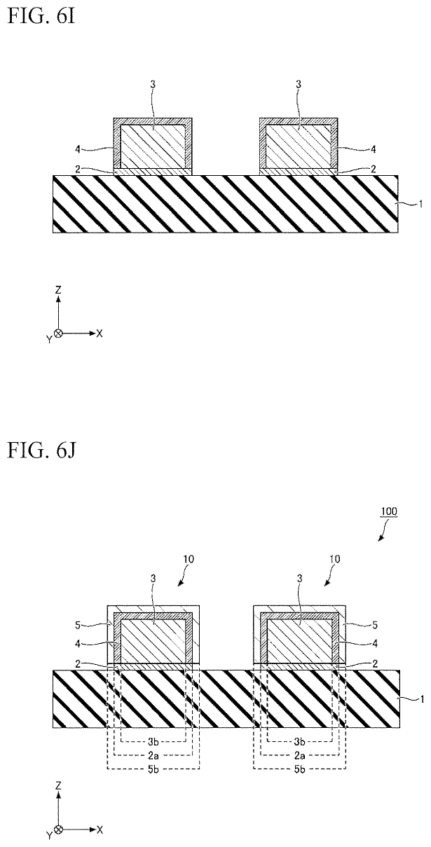

FIG. 5 is a flowchart illustrating an example of a method of manufacturing a ceramic substrate according to the first embodiment. The method of manufacturing a ceramic substrate according to the first embodiment will be described with reference to FIGS. 6A to 6J.

The method of manufacturing a ceramic substrate according to the first embodiment includes providing a first resist layer on an upper surface of a ceramic plate, and exposing the first resist layer to light and developing the first resist layer into a predetermined shape, arranging a seed layer on the upper surface of the ceramic plate exposed from the first resist layer having been exposed to light and developed, on a lateral surface of the first resist layer, and on an upper surface of the first resist layer, providing a second resist layer in order to cover at least a part of an upper surface of the seed layer, and exposing the second resist layer to light and developing the second resist layer into a predetermined shape, in order to expose at least a part of the upper surface of the seed layer arranged on the upper surface of the ceramic plate, arranging, by electrolytic plating, a Cu layer on the upper surface of the seed layer exposed from the second resist layer having been exposed to light and developed, removing a part of the seed layer, the first resist layer, and the second resist layer, arranging an intermediate layer of one layer or two or more layers on an upper surface of the Cu layer and a lateral surface of the Cu layer, and arranging an Au layer on an upper surface of the intermediate layer and a lateral surface of the intermediate layer.

(S1) Exposing First Resist Layer to Light and Developing First Resist Layer into Predetermined Shape

FIG. 6A is a schematic cross-sectional view illustrating an example of a ceramic plate used in the method of manufacturing a ceramic substrate according to the first embodiment. FIG. 6B is a schematic cross-sectional view illustrating an example of providing a first resist layer in the method of manufacturing a ceramic substrate according to the first embodiment. FIG. 6C is a schematic cross-sectional view illustrating an example in which the first resist layer is exposed to light and developed into a predetermined shape in the method of manufacturing a ceramic substrate according to the first embodiment.

In step S1 in which a first resist layer is exposed to light and developed into a predetermined shape, a first resist layer 50 is provided on an upper surface of the ceramic plate 1, and the first resist layer 50 is exposed to light and developed into a predetermined shape.

Specifically, in step S1 in which a first resist layer is exposed to light and developed into a predetermined shape, first, the ceramic plate 1 is prepared. The ceramic plate 1 can be a ceramic precursor before sintering or can be a sintered ceramic. However, a sintered ceramic is preferable, because in the sintered ceramic, no dimensional change occurs due to sintering.

Subsequently, the first resist layer 50 is provided on the upper surface of the ceramic plate 1. At this time, the first resist layer 50 may be provided on the entire upper surface of the ceramic plate 1 or may be provided on a part of the upper surface of the ceramic plate 1. The position at which the first resist layer 50 is provided on the upper surface of the ceramic plate 1 can be appropriately selected in accordance with a desired position at which the region 10 is provided on the upper surface of the ceramic plate 1.

The first resist layer 50 is not particularly limited, and can be formed by using a photoresist composition, a sheet resist (dry film resist), or the like that is commonly used in the technical field of light-emitting elements. Specifically, photoresist compositions composed of various materials and classified into a novolac-diazonaphthoquinone (DNQ) photoresist, a positive photoresist, a negative photoresist, a chemical amplification photoresist, a photo-crosslinking photoresist, a photopolymerization photoresist, and the like, or a dry film resist made of these photoresist compositions can be used as the first resist layer 50. Any commercially available products of these photoresist compositions or the dry film resist can be used. Among these photoresist compositions and dry film resist, the first resist layer 50 is preferably formed by using a negative photoresist.

Examples of a method of forming the first resist layer 50 by using a photoresist composition include a screen coating method, a spin coating method, a roll coating method, a laminator method, a dip coating method, and a spray coating method.

Subsequently, the first resist layer 50 can be formed into a predetermined shape by utilizing, for example, a photolithography method and an etching method. For example, when a negative photoresist is used, the first resist layer 50 is exposed to light by utilizing a mask having an opening of a desired shape in accordance with the region 10.

The exposure amount is not particularly limited, and is preferably appropriately set in a range from about 10 mJ to 50 mJ. Before or after exposing the first resist layer 50 to light, baking can be performed at any temperature during any period of time.

Afterwards, the first resist layer 50 is patterned into a predetermined shape by immersion development, spray development, or the like using a developer that dissolves the resist present in an unexposed portion of the first resist layer 50.

The developer used in this step can be appropriately selected depending on the type of resist being used. Examples of the developer include tetramethylammonium hydroxide (TMAH) and tetrabutylammonium hydroxide (TBAH).

### (S2) Arranging Seed Layer

FIG. 6D is a schematic cross-sectional view illustrating an example of arranging a seed layer in the method of manufacturing a ceramic substrate according to the first embodiment.

In step S2 in which a seed layer is arranged, the seed layer 2 is arranged on the upper surface of the ceramic plate 1 exposed from the first resist layer 50 having been exposed to light and developed, on a lateral surface of the first resist layer 50, and on an upper surface of the first resist layer 50.

For example, the seed layer 2 can be formed by a method known in the related field, such as electrolytic plating, electroless plating, vapor deposition, or sputtering, which uses the material of the seed layer 2.

The average thickness of the seed layer 2 can be adjusted by the amount of the material of the seed layer 2 to be applied. In step S2 in which the seed layer is arranged, the seed layer 2 is preferably arranged so as to have a thickness in a range from 1.0 μm to 5.0 μm, and is more preferably arranged so as to have a thickness in a range from 1.2 μm to 3.0 μm.

(S3) Exposing Second Resist Layer to Light and Developing Second Resist Layer into Predetermined Shape

FIG. 6E is a schematic cross-sectional view illustrating an example of providing a second resist layer in the method of manufacturing a ceramic substrate according to the first embodiment. FIG. 6F is a schematic cross-sectional view illustrating an example in which the second resist layer is exposed to light and developed into a predetermined shape in the method of manufacturing a ceramic substrate according to the first embodiment.

In step S3 in which a second resist layer is exposed to light and developed into a predetermined shape, a second resist layer 51 is provided so as to cover at least a part of the upper surface of the seed layer 2, and the second resist layer 51 is exposed to light and developed into a predetermined shape so as to expose at least a part of the upper surface of the seed layer 2 arranged on the upper surface of the ceramic plate 1.

A position where the second resist layer 51 is provided can be appropriately selected in accordance with the desired position where the region 10 is provided on the upper surface of the seed layer 2. However, the second resist layer 51 is preferably provided at a position where at least the first resist layer 50 can be removed at the same time when the second resist layer 51 is removed.

The second resist layer 51 is not particularly limited, and can be formed by using any of photoresist compositions commonly used in the technical field of light-emitting elements. For example, a photoresist composition same as or similar to the one used for the first resist layer 50 can be used. Among these photoresist compositions, the second resist layer 51 is preferably formed by using a negative photoresist.

Examples of a method of forming the second resist layer 51 by using a photoresist composition include a screen coating method, a spin coating method, a roll coating method, a laminator method, a dip coating method, and a spray coating method.

Subsequently, the second resist layer 51 can be formed into a predetermined shape by utilizing, for example, a photolithography method and an etching method. For example, when a negative photoresist is used, the second resist layer 51 is exposed to light by utilizing a mask having an opening of a desired shape in accordance with the region 10. For example, a mask is used to form the second resist layer 51 on the seed layer 2 arranged on the first resist layer 50, so that the first resist layer 50, the second resist layer 51, and the seed layer 2 between the first resist layer 50 and the second resist layer 51 can be simultaneously removed in step S5 to be described later, in which a part of the seed layer, the first resist layer, and the second resist layer are removed.

The exposure amount is not particularly limited, and is preferably appropriately set in a range from about 10 mJ to 50 mJ. Before or after exposing the second resist layer 51 to light, baking can be performed at any temperature during any period of time.

Afterwards, the second resist layer 51 is patterned into a predetermined shape by immersion development, spray development, or the like using a developer that dissolves the resist present in an unexposed portion of the second resist layer 51.

The developer used in this step can be appropriately selected depending on the type of resist being used. Examples of the developer include tetramethylammonium hydroxide (TMAH) and tetrabutylammonium hydroxide (TBAH).

In the method of manufacturing a ceramic substrate according to the first embodiment, in step S3 in which the second resist layer is exposed to light and developed into a predetermined shape, it is preferable to expose the second resist layer 51 to light and develop the second resist layer 51 so that at least a part of the upper surface of the seed layer 2 arranged on the upper surface of the ceramic plate 1 is exposed from the second resist layer 51, without exposing the lateral surface of the first resist layer 50 and the seed layer 2 arranged on the upper surface of the first resist layer 50. That is, it is preferable to remove the second resist layer 51 between adjacent first resist layers 50.

### (S4) Arranging Cu Layer

FIG. 6G is a schematic cross-sectional view illustrating an example of arranging a Cu layer in the method of manufacturing a ceramic substrate according to the first embodiment.

In step S4 in which a Cu layer is arranged, the Cu layer 3 is arranged by electrolytic plating on the upper surface of the seed layer 2 exposed from the second resist layer 51 having been exposed to light and developed. The average thickness of the Cu layer 3 can be adjusted by the amount of the plating solution containing Cu to be applied. In this step, the seed layer 2 is not arranged on a lateral surface of the Cu layer 3.

For example, the plating solution contains Cu particles and a solvent, and can further contain a resin as necessary. The plating solution is bonded to the seed layer 2.

### (S5) Removing Part of Seed Layer, First Resist Layer, and Second Resist Layer

FIG. 6H is a schematic cross-sectional view illustrating an example of removing a part of the seed layer, the first resist layer, and the second resist layer in the method of manufacturing a ceramic substrate according to the first embodiment.

In step S5 in which a part of the seed layer, the first resist layer, and the second resist layer are removed, the first resist layer 50 and the second resist layer 51 are preferably removed completely. Examples of the part of the seed layer 2 include the seed layer 2 between the first resist layer 50 and the second resist layer 51, and the seed layer 2 arranged on the lateral surface of the first resist layer 50. Thus, a layered structure is formed that includes the ceramic plate 1, the seed layer 2, and the Cu layer 3 having a predetermined shape.

For example, the part of the seed layer 2, the first resist layer 50, and the second resist layer 51 can be removed by using a lift-off method. As the solvent used in the lift-off method, a stripper solution can be used, for example. For example, the part of the seed layer 2, the first resist layer 50, and the second resist layer 51 are removed together by ultrasonic cleaning.

### (S6) Arranging Intermediate Layer

FIG. 6I is a schematic cross-sectional view illustrating an example of arranging an intermediate layer in the method of manufacturing a ceramic substrate according to the first embodiment.

In step S6 in which an intermediate layer is arranged, the intermediate layer 4 of one layer is arranged on the upper surface of the Cu layer 3 and the lateral surface of the Cu layer 3. The intermediate layer 4 is preferably arranged so as to cover the upper surface of the seed layer 2 arranged on the upper surface of the ceramic plate 1. The average thickness of the intermediate layer 4 can be adjusted by the amount of the material of the intermediate layer 4 to be applied.

For example, the intermediate layer 4 can be formed by a method known in the related field, such as electrolytic plating, electroless plating, vapor deposition, or sputtering.

### (S7) Arranging Au Layer

FIG. 6J is a schematic cross-sectional view illustrating an example of arranging an Au layer in the method of manufacturing a ceramic substrate according to the first embodiment.

In step S7 in which an Au layer is arranged, the Au layer 5 is arranged on the upper surface of the intermediate layer 4 and the lateral surface of the intermediate layer 4. Specifically, the Au layer 5 can be formed by applying a material of the Au layer 5 from above the intermediate layer 4 and from the side of the intermediate layer 4. The average thickness of the Au layer 5 can be adjusted by the amount of the material of the Au layer 5 to be applied.

For example, the Au layer 5 can be formed by a method known in the related field, such as electrolytic plating, electroless plating, vapor deposition, or sputtering.

According to the above-described method, the ceramic substrate 100 is formed, the ceramic substrate 100 including the ceramic plate 1, the seed layer 2 arranged on the upper surface of the ceramic plate 1, the Cu layer 3 arranged on the upper surface of the seed layer 2, the intermediate layer 4 of one layer arranged on the upper surface of the Cu layer 3 and the lateral surface of the Cu layer 3, and the Au layer 5 arranged on the upper surface of the intermediate layer 4 and the lateral surface of the intermediate layer 4. The upper surface of the seed layer 2 and the intermediate layer 4 contact each other. The upper surface of the ceramic plate 1 and the Au layer 5 do not contact each other. The edge portion 2a of the upper surface of the seed layer 2 is located outside the edge portion 3b of the lower surface of the Cu layer 3 in the horizontal direction. The edge portion 2a of the upper surface of the seed layer 2 is located inside the edge portion 5b of the lower surface of the Au layer 5 in the horizontal direction.

In the method of manufacturing a ceramic substrate according to the first embodiment, in the ceramic substrate 100 eventually formed, the edge portion 2a of the upper surface of the seed layer 2 is located outside the edge portion 3b of the lower surface of the Cu layer 3. Therefore, the upper surface of the seed layer 2 and the lower surface of the intermediate layer 4 contact each other, so that the Cu layer 3 is completely covered with the seed layer 2 and the intermediate layer 4. Thus, corrosion of the lower surface of the Cu layer 3 can be suppressed, and the ceramic substrate 100 having increased reliability can be obtained.

### Second Embodiment

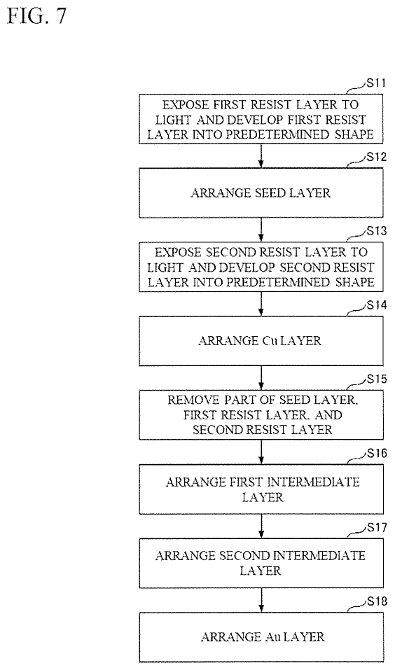

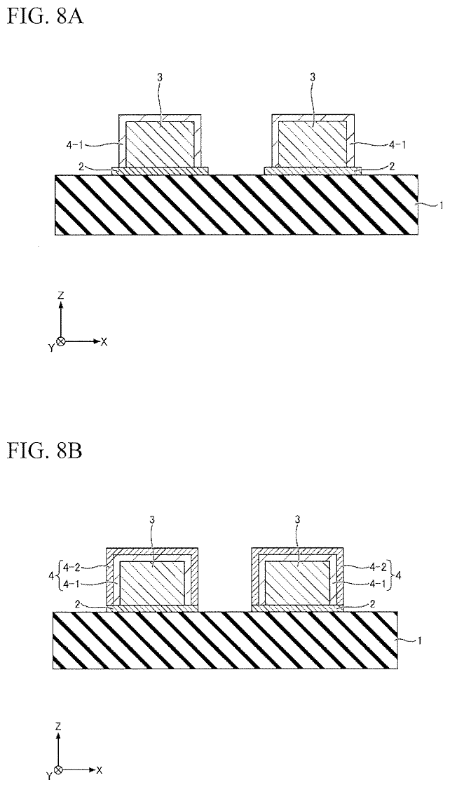

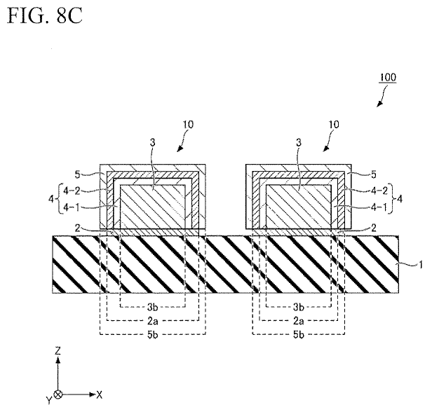

FIG. 7 is a flowchart illustrating an example of a method of manufacturing a ceramic substrate according to a second embodiment. A method of manufacturing a ceramic substrate according to the second embodiment will be described with reference to FIGS. 8A to 8C.

The method of manufacturing a ceramic substrate according to the second embodiment is the same as the method of manufacturing a ceramic substrate according to the first embodiment, except that two or more intermediate layers 4 are formed.

### (S16) Arranging First Intermediate Layer

FIG. 8A is a schematic cross-sectional view illustrating an example of arranging a first intermediate layer in the method of manufacturing a ceramic substrate according to the second embodiment.

In step S16 in which a first intermediate layer is arranged, a first intermediate layer 4-1 is arranged on the upper surface of the Cu layer 3 and the lateral surface of the Cu layer 3. The average thickness of the first intermediate layer 4-1 can be adjusted by the amount of material of the first intermediate layer 4-1 to be applied.

The material of the first intermediate layer 4-1 can be appropriately selected. However, in step S16 in which the first intermediate layer is arranged, it is preferable to arrange a Ni layer as the first intermediate layer 4-1 on the upper surface of the Cu layer 3 and the lateral surface of the Cu layer 3.

### (S17) Arranging Second Intermediate Layer

FIG. 8B is a schematic cross-sectional view illustrating an example of arranging a second intermediate layer in the method of manufacturing a ceramic substrate according to the second embodiment.

In step S17 in which a second intermediate layer is arranged, a second intermediate layer 4-2 is arranged on the upper surface of the first intermediate layer 4-1 and the lateral surface of the first intermediate layer 4-1. The average thickness of the second intermediate layer 4-2 can be adjusted by the amount of material of the second intermediate layer 4-2 to be applied.

The material of the second intermediate layer 4-2 can be appropriately selected. However, in step S17 in which the second intermediate layer 4-2 is arranged, a Pd layer is preferably arranged as the second intermediate layer 4-2 on an upper surface of the Ni layer serving as the first intermediate layer 4-1 and a lateral surface of the Ni layer serving as the first intermediate layer 4-1.

### (S18) Arranging Au Layer

FIG. 8C is a schematic cross-sectional view illustrating an example of arranging an Au layer in the method of manufacturing a ceramic substrate according to the second embodiment.

In step S18 in which an Au layer is arranged, the Au layer 5 is arranged on an upper surface of the second intermediate layer 4-2 and a lateral surface of the second intermediate layer 4-2. In step S18 in which an Au layer is arranged, when the second intermediate layer 4-2 is a Pd layer, the Au layer 5 is arranged on an upper surface of the Pd layer serving as the second intermediate layer 4-2 and a lateral surface of the Pd layer serving as the second intermediate layer 4-2.

According to the above-described method, the ceramic substrate 100 includes the ceramic plate 1, the seed layer 2 arranged on the upper surface of the ceramic plate 1, the Cu layer 3 arranged on the upper surface of the seed layer 2, the first intermediate layer 4-1 and the second intermediate layer 4-2 arranged on the upper surface of the Cu layer 3 and the lateral surface of the Cu layer 3, and the Au layer 5 arranged on the upper surface of the second intermediate layer 4-2 and the lateral surface of the second intermediate layer 4-2. The upper surface of the seed layer 2 contacts the first intermediate layer 4-1 and the second intermediate layer 4-2. However, the upper surface of the ceramic plate 1 and the Au layer 5 do not contact each other. The ceramic substrate 100 is formed in which the edge portion 2a of the upper surface of the seed layer 2 is located outside the edge portion 3b of the lower surface of the Cu layer 3 in the horizontal direction, and the edge portion 2a of the upper surface of the seed layer 2 is located inside the edge portion 5b of the lower surface of the Au layer 5 in the horizontal direction.

In the method of manufacturing a ceramic substrate according to the second embodiment, a case in which the intermediate layer 4 includes two layers is described. However, in the ceramic substrate 100 according to an embodiment of the present disclosure, the intermediate layer 4 can include three or more layers. In a case in which the intermediate layer 4 includes three or more layers, a third intermediate layer, a fourth intermediate layer, and the like can be sequentially formed by a method same as or similar to step S17 in which the second intermediate layer is arranged.

### Third Embodiment

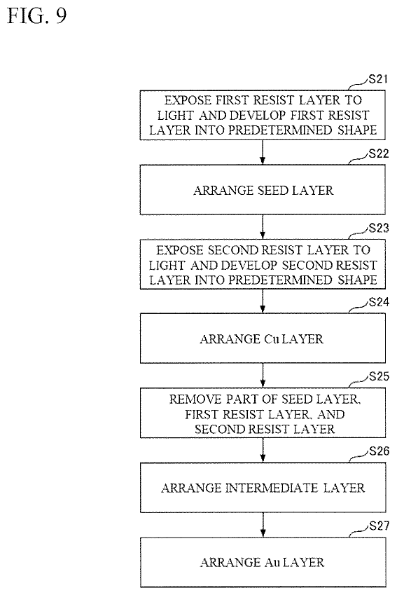

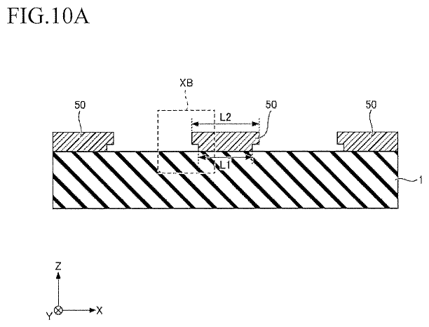

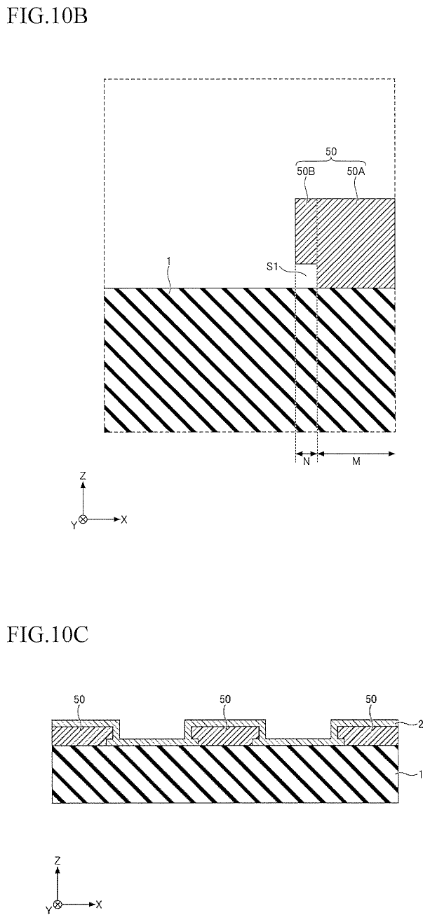

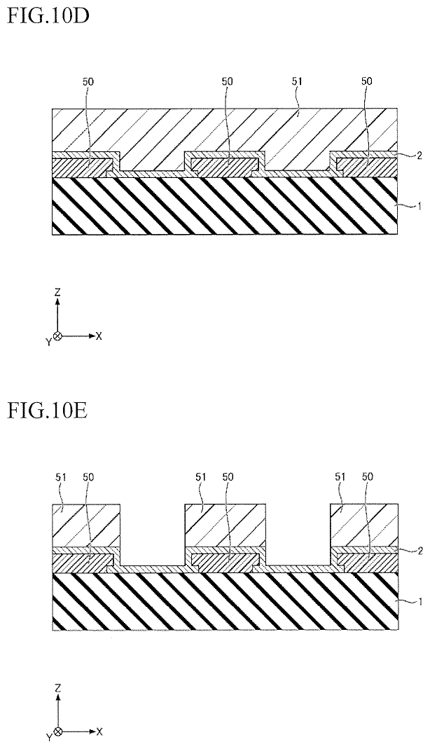

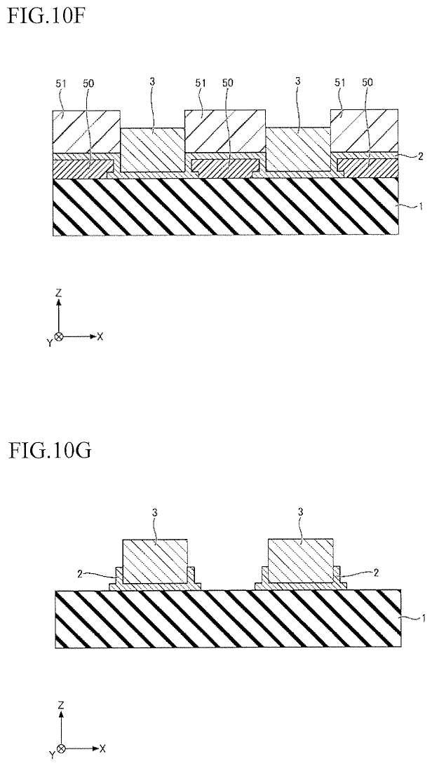

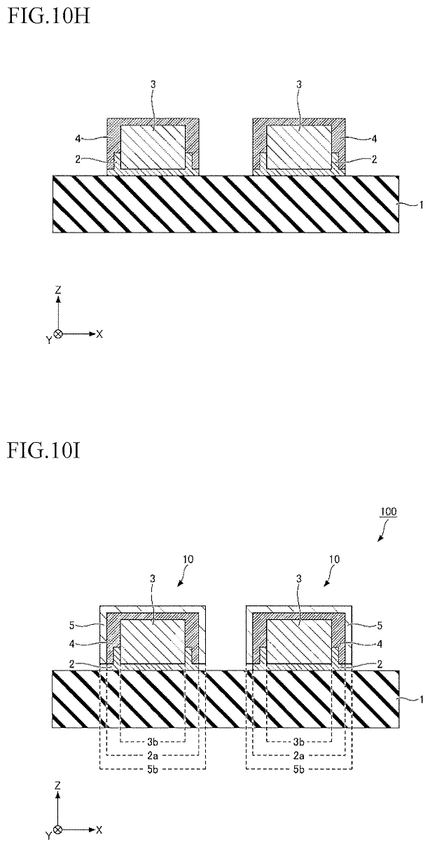

FIG. 9 is a flowchart illustrating an example of a method of manufacturing a ceramic substrate according to a third embodiment. A method of manufacturing a ceramic substrate according to the third embodiment will be described with reference to FIGS. 10A to 10I.

The method of manufacturing a ceramic substrate according to the third embodiment is the same as the method of manufacturing a ceramic substrate according to the first embodiment, except that the first resist layer has a predetermined shape such that a length L1 of the lower surface of the first resist layer 50 in a cross section in the thickness direction of the ceramic plate 1 is smaller than a length L2 of the upper surface of the first resist layer 50, and the seed layer 2 is arranged on a part of the lateral surface of the Cu layer 3.

(S21) Exposing First Resist Layer to Light and Developing First Resist Layer into Predetermined Shape

FIG. 10A is a schematic cross-sectional view illustrating an example in which the first resist layer is exposed to light and developed into a predetermined shape in the method of manufacturing a ceramic substrate according to the third embodiment. FIG. 10B is an enlarged cross-sectional view of a region XB in FIG. 10A.

In step S21, in which the first resist layer is exposed to light and developed into a predetermined shape, the first resist layer 50 is exposed to light and developed such that the length L1 of the lower surface of the first resist layer 50 in a cross section in the thickness direction of the ceramic plate 1 is smaller than the length L2 of the upper surface of the first resist layer 50. In other words, the length L1 of the lower surface of the first resist layer 50 and the length L2 of the upper surface of the first resist layer 50 satisfy L1<L2.

For example, in S21 in which the first resist layer 50 is exposed to light and developed into a predetermined shape, the first resist layer 50 is exposed to light and developed so that, in a cross-sectional view, the shape of the first resist layer 50 in a cross section in the thickness direction of the ceramic plate 1 has a main portion 50A of the first resist layer 50 contacting a first region M on the upper surface of the ceramic plate 1 and a protruding portion 50B protruding from the main portion 50A above a second region N without contacting the second region N on the upper surface of the ceramic plate 1 adjacent to the first region M. Thus, a space S1 is formed between the upper surface of the ceramic plate 1 and the lower surface of the protruding portion 50B. The length of the first region M in the X-axis direction on the upper surface of the ceramic plate 1 corresponds to the length L1 of the lower surface of the first resist layer 50.

### (S22) Arranging Seed Layer

FIG. 10C is a schematic cross-sectional view illustrating an example of arranging a seed layer in the method of manufacturing a ceramic substrate according to the third embodiment.

In step S22 in which a seed layer is arranged, the seed layer 2 is arranged so as to continuously cover the lateral surface of the first resist layer 50 and the upper surface of the ceramic plate 1 exposed from the first resist layer 50. Specifically, in step S22 in which the seed layer is arranged, the seed layer 2 is arranged on the upper surface of the ceramic plate 1 exposed from the first resist layer 50 having been exposed to light and developed, on the lateral surface of the first resist layer 50, and on the upper surface of the first resist layer 50, and thus, the seed layer 2 is also arranged on the space S1.

(S23) Exposing Second Resist Layer to Light and Developing Second Resist Layer into Predetermined Shape

FIG. 10D is a schematic cross-sectional view illustrating an example of providing a second resist layer in the method of manufacturing a ceramic substrate according to the third embodiment. FIG. 10E is a schematic cross-sectional view illustrating an example in which the second resist layer is exposed to light and developed into a predetermined shape in the method of manufacturing a ceramic substrate according to the third embodiment.

In step S23 in which the second resist layer is exposed to light and developed into a predetermined shape, it is preferable to expose the second resist layer to light and develop the second resist layer so that the seed layer 2 arranged on the lateral surface of the first resist layer 50 is exposed.

### (S24) Arranging Cu Layer

FIG. 10F is a schematic cross-sectional view illustrating an example of arranging a Cu layer in the method of manufacturing a ceramic substrate according to the third embodiment. In the method of manufacturing a ceramic substrate according to the third embodiment, in step S24 in which a Cu layer is arranged, in addition to arranging the Cu layer 3 by electrolytic plating on the upper surface of the seed layer 2 exposed from the second resist layer 51 having been exposed to light and developed, the Cu layer 3 is preferably arranged by electrolytic plating on the seed layer 2 arranged on the lateral surface of the first resist layer 50. The seed layer 2 is continuously extended, and thus, the Cu layer 3 can be arranged by electrolytic plating.

### (S25) Removing Part of Seed Layer, First Resist Layer, and Second Resist Layer

FIG. 10G is a schematic cross-sectional view illustrating an example of removing a part of the seed layer, the first resist layer, and the second resist layer in the method of manufacturing a ceramic substrate according to the third embodiment.

In step S25 in which a part of the seed layer, the first resist layer, and the second resist layer are removed, the seed layer 2 arranged on the upper surface of the first resist layer 50 and the lower surface of the second resist layer 51 is removed, while the seed layer 2 arranged on the lateral surface of the first resist layer 50, and the seed layer 2 arranged on the upper surface of the ceramic plate 1 and the lower surface of the first resist layer 50 are not removed.

### (S26) Arranging Intermediate Layer

FIG. 10H is a schematic cross-sectional view illustrating an example of arranging an intermediate layer in the method of manufacturing a ceramic substrate according to the third embodiment.

In step S26 in which an intermediate layer is arranged, the intermediate layer 4 is arranged so as to cover the upper surface of the Cu layer 3 and the seed layer 2 arranged on the lateral surface of the Cu layer 3. The intermediate layer 4 is also arranged on the lateral surface of the Cu layer 3 that is not covered by the seed layer 2.

### (S27) Arranging Au Layer

FIG. 10I is a schematic cross-sectional view illustrating an example of arranging an Au layer in the method of manufacturing a ceramic substrate according to the third embodiment.

According to the above-described method, the ceramic plate 1, the seed layer 2 arranged on the upper surface of the ceramic plate 1, the Cu layer 3 arranged on the upper surface of the seed layer 2, the intermediate layer 4 of one layer arranged on the upper surface of the Cu layer 3 and the lateral surface of the Cu layer 3, and the Au layer 5 arranged on the upper surface of the intermediate layer 4 and the lateral surface of the intermediate layer 4 are provided, and the upper surface of the seed layer 2 and the intermediate layer 4 contact each other. However, the upper surface of the ceramic plate 1 and the Au layer 5 do not contact each other. The ceramic substrate 100 is formed in which the edge portion 2a of the upper surface of the seed layer 2 is located outside the edge portion 3b of the lower surface of the Cu layer 3 in the horizontal direction, the edge portion 2a of the upper surface of the seed layer 2 is located inside the edge portion 5b of the lower surface of the Au layer 5 in the horizontal direction, the seed layer 2 is continuously arranged from the lower surface of the Cu layer 3 to a part of the lateral surface of the Cu layer 3, and the intermediate layer 4 is arranged so as to cover the seed layer 2 arranged on a part of the lateral surface of the Cu layer 3.

In the ceramic substrate 100 formed by the method of manufacturing a ceramic substrate according to the third embodiment, as compared with the ceramic substrate 100 formed by the method of manufacturing a ceramic substrate according to the first embodiment, the seed layer 2 is arranged on a part of the lateral surface of the Cu layer 3. Therefore, a boundary between the lower surface of the intermediate layer 4 and the upper surface of the seed layer 2 is not created on the lower surface of the Cu layer 3, and it is possible to more reliably prevent contact between the Cu layer 3 and the external environment such as air. In addition, corrosion can be further suppressed, and the ceramic substrate 100 having further increased reliability can be obtained.

### Fourth Embodiment

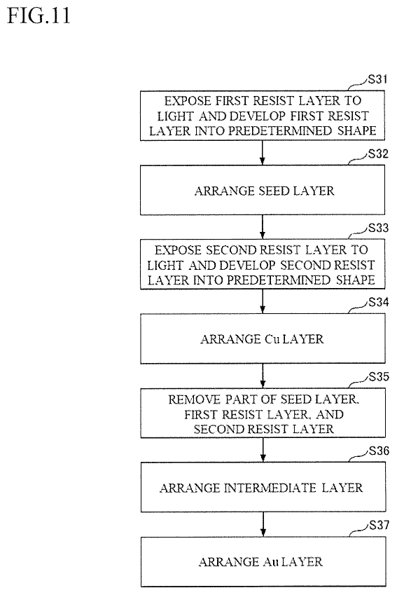

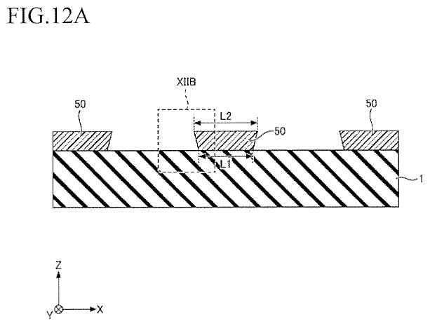

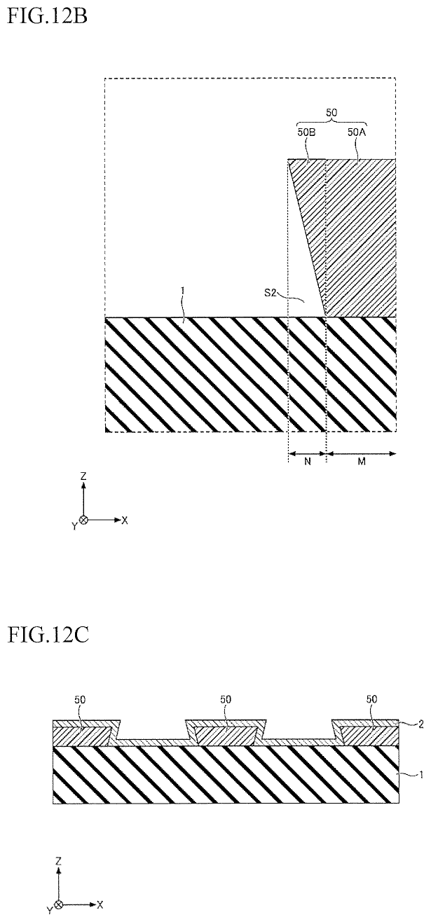

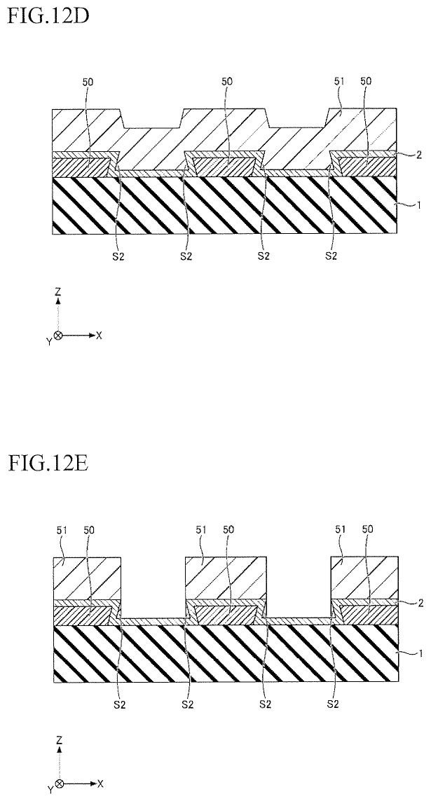

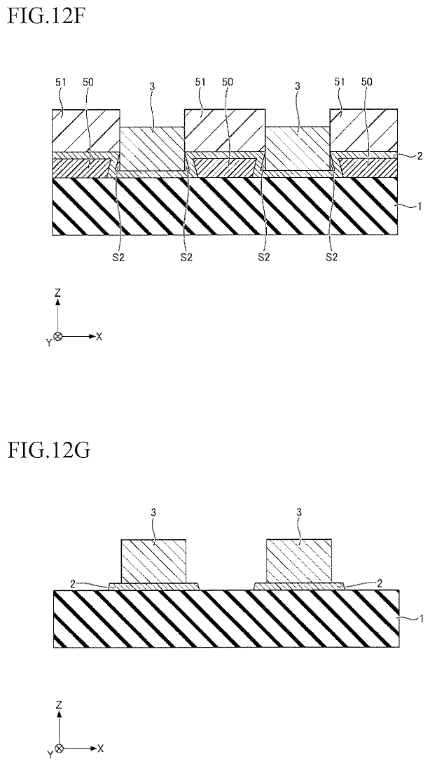

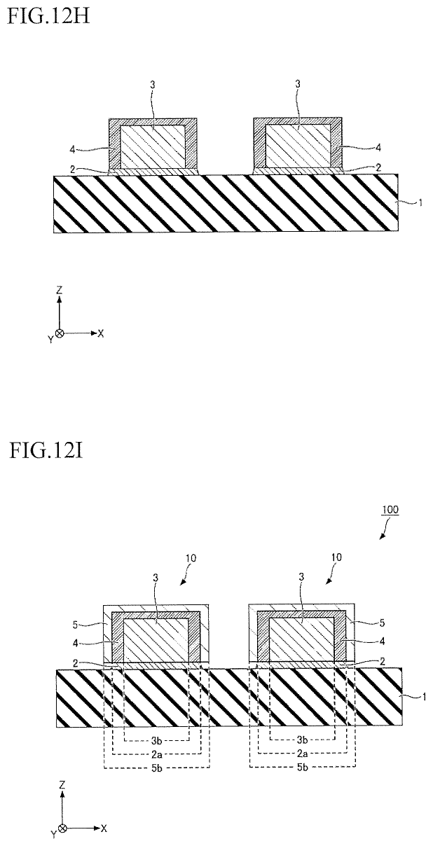

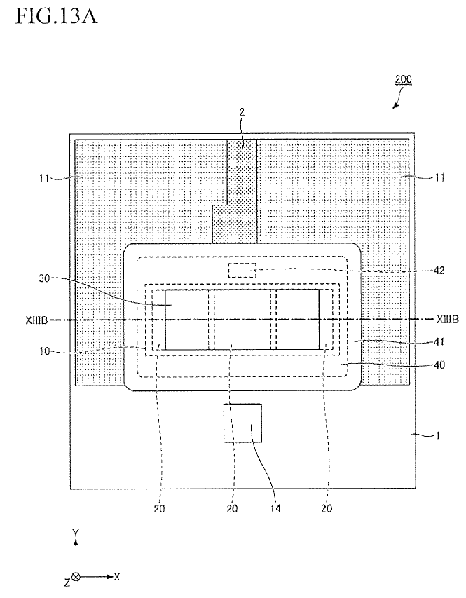

FIG. 11 is a flowchart illustrating an example of a method of manufacturing a ceramic substrate according to a fourth embodiment. A method of manufacturing a ceramic substrate according to the fourth embodiment will be described with reference to FIGS. 12A to 12I.

The method of manufacturing a ceramic substrate according to the fourth embodiment is the same as the method of manufacturing a ceramic substrate according to the third embodiment, except that the seed layer 2 is not arranged on the lateral surface of the Cu layer 3 and the first resist layer 50 is formed in such a manner that the first resist layer 50 has an overhanging shape (also referred to as an inverted tapered shape) in a cross-sectional view, that is, the first resist layer 50 has a shape in a cross-sectional view such that the width (the length in the X-axis direction) of the first resist layer 50 in a cross-sectional view decreases from the upper surface of the first resist layer 50 toward the lower surface of the first resist layer 50.

(S31) Exposing First Resist Layer to Light and Developing First Resist Layer into Predetermined Shape

FIG. 12A is a schematic cross-sectional view illustrating an example in which the first resist layer is exposed to light and developed into a predetermined shape in the method of manufacturing a ceramic substrate according to the fourth embodiment. FIG. 12B is an enlarged cross-sectional view of a region XIIB in FIG. 12A.

In step S31 in which the first resist layer 50 is exposed to light and developed into a predetermined shape, the first resist layer 50 is exposed to light and developed so that, in a cross-sectional view, the shape of the first resist layer 50 in a cross section in the thickness direction of the ceramic plate 1 includes the main portion 50A of the first resist layer 50 contacting the first region M on the upper surface of the ceramic plate 1, and the protruding portion 50B protruding from the main portion 50A above the second region N without contacting the second region N on the upper surface of the ceramic plate 1 adjacent to the first region M. Thus, a space S2 is formed between the upper surface of the ceramic plate 1 and the lower surface of the protruding portion 50B.

### (S32) Arranging Seed Layer

FIG. 12C is a schematic cross-sectional view illustrating an example of arranging a seed layer in the method of manufacturing a ceramic substrate according to the fourth embodiment.

(S33) Exposing Second Resist Layer to Light and Developing Second Resist Layer into Predetermined Shape

FIG. 12D is a schematic cross-sectional view illustrating an example of providing a second resist layer in the method of manufacturing a ceramic substrate according to the fourth embodiment. FIG. 12E is a schematic cross-sectional view illustrating an example in which the second resist layer is exposed to light and developed into a predetermined shape in the method of manufacturing a ceramic substrate according to the fourth embodiment.

In step S33 in which the second resist layer is exposed to light and developed into a predetermined shape, a sheet resist, specifically, a dry film is used as the second resist layer 51. When the dry film is used as the second resist layer 51 and vacuum is applied, an air layer between the second resist layer 51, and the first resist layer 50 and the seed layer 2 can be removed, and the second resist layer 51 can also be provided in the space S2.

Subsequently, the second resist layer 51 is exposed to light and developed so that the second resist layer 51 arranged on the upper surface of the seed layer 2 and the second resist layer 51 arranged on the lateral surface of the seed layer 2 in the space S2 remain. Thus, the seed layer 2 arranged on the upper surface of the ceramic plate 1 is exposed from the second resist layer 51.

However, instead of using the sheet resist as the second resist layer, a photoresist composition or the like commonly used in the technical field of the light-emitting elements can be used to arrange the second resist layer 51 on the upper surface of the seed layer 2 arranged on the upper surface of the ceramic plate 1, on the upper surface of the seed layer 2 arranged on the upper surface of the first resist layer 50, and on the lateral surface of the seed layer 2 arranged on the lateral surface of the first resist layer 50. In this case, the second resist layer 51 is also arranged above the ceramic plate 1, that is, on the side of the first resist layer 50 between adjacent first resist layers 50, and in the space S2. Subsequently, the second resist layer 51 is exposed to light and developed so that the upper surface of the ceramic plate 1 is exposed. Thus, the seed layer 2 arranged on the upper surface of the ceramic plate 1 is exposed from the second resist layer 51. The expression “above the ceramic plate 1” does not imply that the ceramic plate 1 and the second resist layer 51 contact each other. The seed layer 2 is arranged between the ceramic plate 1 and the second resist layer 51. The expression “on the side of the first resist layer 50” does not imply that the lateral surface of the first resist layer 50 and the second resist layer 51 contact each other. The seed layer 2 is arranged between the lateral surface of the first resist layer 50 and the second resist layer 51.

### (S34) Arranging Cu Layer

FIG. 12F is a schematic cross-sectional view illustrating an example of arranging a Cu layer in the method of manufacturing a ceramic substrate according to the fourth embodiment.

The Cu layer 3 is formed by applying a plating solution containing Cu from above the seed layer 2 exposed from the second resist layer 51. At this time, the second resist layer 51 is arranged in the space S2, and thus, the plating solution is not applied to the space S2.

### (S35) Removing Part of Seed Layer, First Resist Layer, and Second Resist Layer

FIG. 12G is a schematic cross-sectional view illustrating an example of removing a part of the seed layer, the first resist layer, and the second resist layer in the method of manufacturing a ceramic substrate according to the fourth embodiment.

In step S35 in which a part of the seed layer, the first resist layer, and the second resist layer are removed, the first resist layer 50, the seed layer 2 arranged on the upper surface of the first resist layer 50, the seed layer 2 arranged on the lateral surface of the first resist layer 50, the second resist layer 51 arranged on the upper surface of the seed layer 2 arranged on the upper surface of the first resist layer 50, and the second resist layer 51 arranged on the lateral surface of the seed layer 2 arranged on the lateral surface of the first resist layer 50 are removed.

### (S36) Arranging Intermediate Layer

FIG. 12H is a schematic cross-sectional view illustrating an example of arranging an intermediate layer in the method of manufacturing a ceramic substrate according to the fourth embodiment.

### (S37) Arranging Au Layer

FIG. 12I is a schematic cross-sectional view illustrating an example of arranging an Au layer in the method of manufacturing a ceramic substrate according to the fourth embodiment.

According to the above-described method, the ceramic plate 1, the seed layer 2 arranged on the upper surface of the ceramic plate 1, the Cu layer 3 arranged on the upper surface of the seed layer 2, the intermediate layer 4 of one layer arranged on the upper surface of the Cu layer 3 and the lateral surface of the Cu layer 3, and the Au layer 5 arranged on the upper surface of the intermediate layer 4 and the lateral surface of the intermediate layer 4 are provided, and the upper surface of the seed layer 2 and the intermediate layer 4 contact each other. The upper surface of the ceramic plate 1 and the Au layer 5 do not contact each other. However, the upper surface of the ceramic plate 1 and the Au layer 5 can contact each other. The ceramic substrate 100 is formed in which the edge portion 2a of the upper surface of the seed layer 2 is located outside the edge portion 3b of the lower surface of the Cu layer 3 in the horizontal direction. The first resist layer 50 is formed so as to provide the space S2 in this manner, so that the area of the seed layer 2 extending outward from the Cu layer 3 can be increased. The seed layer 2 and the Au layer 5 contact each other, so that corrosion of the lower surface of the Cu layer 3 can be further suppressed, and thus, the ceramic substrate having increased reliability can be obtained.

### Light-Emitting Device

A light-emitting device 200 according to an embodiment includes the ceramic substrate 100 according to the embodiment and a light-emitting element 20 arranged on the ceramic substrate 100. Preferably, the light-emitting device 200 according to the embodiment further includes a reflective member 40 arranged on the upper surface of the ceramic substrate 100. The light-emitting device 200 according to the embodiment can include a bonding member 60 electrically connecting the light-emitting element 20 and the ceramic substrate 100, a light-transmissive member 30 arranged on the upper surface of the light-emitting element 20, and a frame body 41 surrounding the light-emitting element 20 on the ceramic substrate 100.

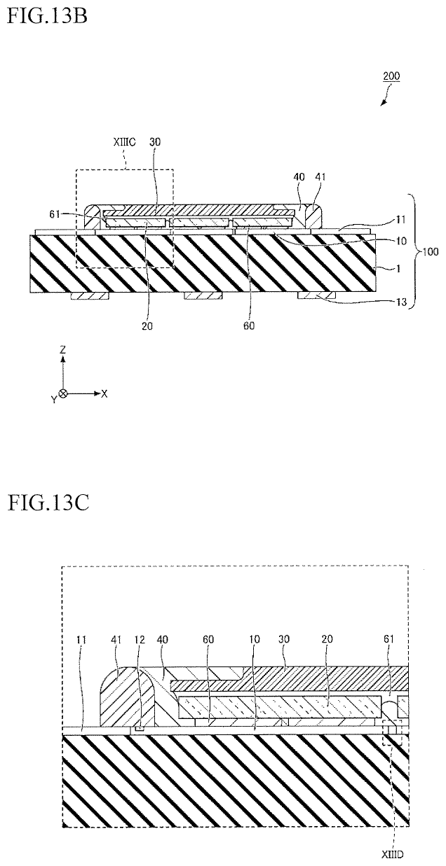

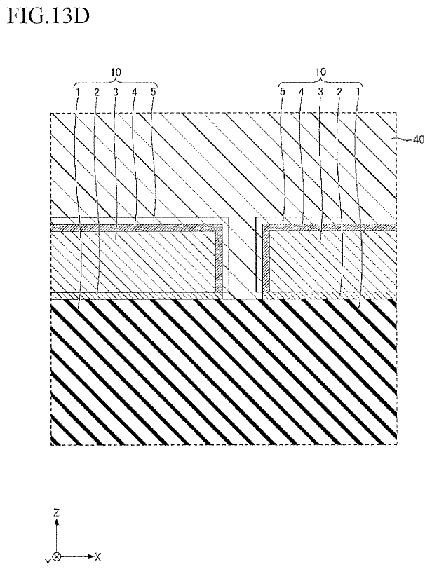

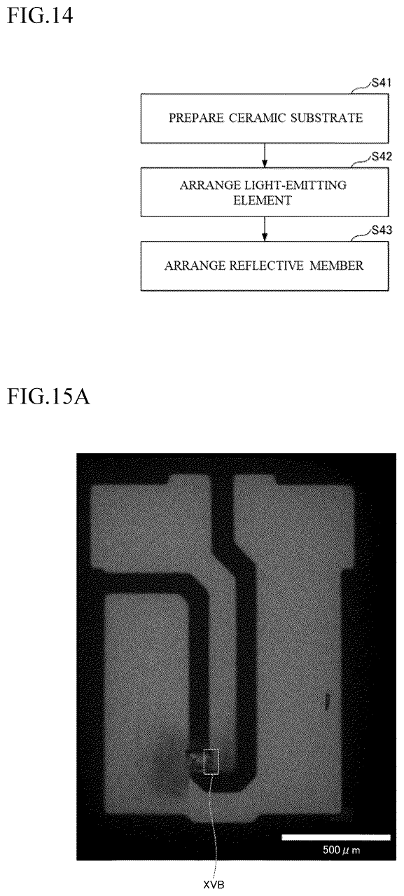

FIG. 13A is a schematic top view illustrating an example of a light-emitting device according to an embodiment. FIG. 13B is a schematic cross-sectional view in a layering direction, taken along line XIIIB-XIIIB in FIG. 13A. FIG. 13C is an enlarged cross-sectional view of a region XIIIC in FIG. 13B. FIG. 13D is an enlarged cross-sectional view of a region XIIID in FIG. 13C. Components of the light-emitting device 200 will be described below.

The light-emitting device 200 is a device in which the light-emitting element 20 is arranged on the ceramic substrate 100 to emit light. In the light-emitting device 200, the region 10 of the ceramic substrate 100 in which the seed layer 2, the Cu layer 3, the intermediate layer 4, and the Au layer 5 are layered, serves as an element placement region on which the light-emitting element 20 is mounted.

Furthermore, in the light-emitting device 200, the pad portion 11 of the ceramic substrate 100 serves as an external connection region for ensuring an electric connection with the outside of the light-emitting device 200. The pad portion 11 is arranged outside the frame body 41. In a plan view of the light-emitting device 200, a boundary between the region 10 and the pad portion 11 is arranged inside an outer edge of the frame body 41.

The frame body 41 has a substantially rectangular shape in a plan view, and is formed such that three sides of the rectangle cover the region 10 or the pad portion 11.

The light-emitting device 200 includes the ceramic substrate 100, and thus, the region 10 and the pad portion 11, which are wiring layers using different materials, can be arranged in the element placement region and the external connection region, respectively. Thus, the element placement region can serve as a wiring layer suitable for a bonding material used for bonding the light-emitting element 20, and the external connection region can serve as a wiring layer suitable for a power supply member from the outside. Therefore, the light-emitting element 20 and the ceramic substrate 100 can be bonded stronger and more reliably, while the ceramic substrate 100 and the power supply member supplying power from the outside can be bonded stronger and more reliably.

### Light-Emitting Element 20

A light-emitting diode is preferably used as the light-emitting element 20. The composition of the light-emitting element 20 is not particularly limited and any composition can be used in accordance with a desired light-emitting wavelength. For example, a nitride semiconductor (InₓAl_{y}Ga_{1-x-y}N, 0≤X, 0≤Y, X+Y≤1) or GaP, which can emit blue or green light, or GaAlAs or AlInGaP, which can emit red light, can be used. These materials can be used alone or in combination of two or more types. The dimensions and the shape of the light-emitting element 20 can be appropriately selected in accordance with the purpose of use.

The light-emitting element 20 is normally formed by layering semiconductor layers on a support substrate (for example, a light-transmissive substrate such as sapphire). The support substrate can have protrusions and recessions at a bonding surface with the semiconductor layer. Thus, a critical angle at which light emitted from the semiconductor layer is incident on the substrate can be intentionally changed, and it is possible to easily extract the light to the outside of the support substrate. The support substrate can be removed after the semiconductor layers are layered. For example, the support substrate can be removed by polishing or laser lift off (LLO).

The light-emitting element 20 is mounted face-down with a pair of positive and negative electrodes on a surface side contacting the ceramic substrate 100.

When the light-emitting element 20 is mounted face-down, the light-emitting element 20 can be flip-chip mounted on a mounting substrate. In this case, a surface facing the surface of the light-emitting element 20 on which the pair of electrodes is formed serves as a main light-extracting surface. In the flip-chip mounting, the light-emitting element 20 and the region 10 of the ceramic substrate 100 are electrically connected to each other by using a conductive bonding member in the form of paste such as solder, a bonding member shaped into a thin film, or a bump-shaped bonding member.

The outermost surface of the pair of positive and negative electrodes included in the light-emitting element 20 is preferably made of Au. Au is chemically stable and using Au makes it possible to ensure a reliable electric connection over a long period of time. The outermost surface of the region 10 of the ceramic substrate is the Au layer 5. Therefore, the outermost surfaces of the pair of positive and negative electrodes included in the light-emitting element 20 are made of the same material as the Au layer 5 of the region 10, so that a more reliable connection can be realized.

One light-emitting element 20 can be provided, or a plurality of light-emitting elements 20 can be provided. When a plurality of light-emitting elements 20 are provided, the arrangement thereof is not particularly limited. For example, the light-emitting elements 20 can be arranged in a line in a first direction, or can be arranged in a matrix. When the light-emitting device 200 is designed as a light-emitting device having a horizontally long light distribution pattern suitable for vehicle headlights, the light-emitting elements 20 are preferably arranged in a line in the first direction. For example, when the shape of the ceramic substrate 100 in a plan view in the horizontal direction is a rectangle, the plurality of light-emitting elements 20 are preferably arranged in a line along the first direction being a direction in which a long side extends, and the plurality of light-emitting elements 20 are more preferably arranged at equal intervals in a line along the first direction.

The light-emitting elements 20 are arranged in the region 10 on the ceramic substrate 100. The region 10 is arranged within the frame body 41 and is bonded to the light-emitting elements 20. However, the region 10 includes not only a bonding portion with the light-emitting elements 20, but also a region in the periphery of the bonding portion.

The shape of each of the light-emitting elements 20 in a plan view in the horizontal direction is not particularly limited. For example, the shape can be any of various shapes including a circle, an ellipse, a polygon such as a quadrangle and a hexagon, a polygon with rounded corners, and a shape obtained by combining these shapes. Among these shapes, a quadrangle is preferable, and a rectangle is more preferable. Thus, when the plurality of light-emitting elements 20 are arrayed in the first direction, the plurality of light-emitting elements 20 can be arrayed close to each other, while the distance between lateral surfaces of adjacent ones of the light-emitting elements 20 is kept constant. It is possible to form a light-emitting surface having a horizontally long rectangular shape in its entirety in a plan view in the horizontal direction.

The vertical, horizontal, and height dimensions of the light-emitting elements 20 can be freely set. Among these dimensions, in order to realize the light-emitting device 200 having higher output, each of the light-emitting elements 20 preferably has a large size. In a plan view of the light-emitting element 20 in the horizontal direction, the vertical and horizontal dimensions of the light-emitting element 20 are preferably 600 μm or more, and more preferably 1000 μm or more. Furthermore, from the viewpoint of uniformity of light-emitting intensity, ease of mounting, and the like, the vertical and horizontal dimensions of the light-emitting element 20 are preferably 2000 μm or less.

The light-emitting elements 20 are spaced apart from their adjacent light-emitting elements 20. In this case, the distance between the light-emitting elements 20 is, for example, in a range from 0.1 times to 0.5 times of one side of each of the light-emitting elements 20 along the first direction. Specifically, in the case of using the light-emitting elements 20 each having a substantially square shape in a plan view in which the vertical and horizontal dimensions of each of the light-emitting elements 20 are about 1000 μm, the distance between the adjacent light-emitting elements 20 is in a range from 100 μm to 500 μm.

### Bonding Member 60

The light-emitting elements 20 are normally mounted on the ceramic substrate 100 via the bonding member 60. Examples of the bonding member 60 include solders such as Sn—Bi based solders, Sn—Cu based solders, Sn—Ag based solders, and Au—Sn based solders; eutectic alloys such as alloys having Au and Sn as main components, alloys having Au and Si as main components, and alloys having Au and Ge as main components; conductive pastes made of Ag, Au, or Pd; bumps; anisotropic conductive materials such as anisotropic conductive films (ACF) and anisotropic conductive pastes (ACP); brazing filler materials made of a metal having a low melting point; conductive adhesives combining these materials; and conductive composite adhesives. These materials can be used alone or in combination of two or more types. The light-emitting elements 20 are preferably mounted on the region 10 by the bonding member 60 containing Au among these materials. The outermost surface of the region 10 is the Au layer 5, and thus, using a bonding member containing Au makes it possible to more reliably secure a stable connection over a long period of time.

### Reflective Member 40

The reflective member 40 is a member having light reflectivity. The reflective member 40 is arranged on the upper surface of the ceramic substrate 100 and contacts the Au layer 5 and the seed layer 2. The reflective member 40 is preferably arranged so as to further cover the lateral surface of each of the light-emitting elements 20. In an example of the light-emitting device 200, the reflective member 40 is also arranged between the lower surface of the light-emitting element 20 and the upper surface of the ceramic substrate 100. The reflective member 40 is arranged on the upper surface of the ceramic substrate 100 and contacts the Au layer 5 and the seed layer 2. Therefore, it is possible to suppress lifting (stripping) of the reflective member.

The reflective member 40 preferably has high reflectance, in order that the light from the light-emitting element 20 can be efficiently utilized. The reflective member 40 is preferably white. For example, the reflectance of the reflective member 40 is preferably 90% or more, and more preferably 94% or more at the wavelength of the light emitted from the light-emitting element 20.

The reflective member 40 can also be formed by using a resin material. Examples of the resin material include thermoplastic resins such as acrylic resin, polycarbonate resin, cyclic polyolefin resin, polyethylene terephthalate resin, polyethylene naphthalate resin, and polyester resin, and thermosetting resins such as epoxy resin and silicone resin.

The resin material of the reflective member 40 preferably contains a filler such as a light reflective material. For example, a known material such as titanium oxide, silicon oxide, zirconium oxide, aluminum oxide, zinc oxide, potassium titanate, aluminum nitride, boron nitride, and mullite can be used as the light reflective material. The content of the light reflective material can be appropriately adjusted depending on the intended characteristics and the like of the light-emitting device 200, because the light reflected amount by, and the light transmission amount through, the reflective member 40 can be varied. However, the content of the light reflective material is preferably 30 mass % or more with respect to the total mass of the reflective member 40.

### Light-Transmissive Member 30

The light-transmissive member 30 is preferably arranged on a light-extracting surface of the light-emitting element 20 and is preferably bonded to the light-extracting surface of the light-emitting element 20.

The light-transmissive member 30 has an upper surface and a lower surface. Light emitted from the light-emitting element 20 is incident on the lower surface of the light-transmissive member 30 and is emitted to the outside from the upper surface of the light-transmissive member 30 using the upper surface of the light-transmissive member 30 as a light-extracting surface. The light-transmissive member 30 is preferably a member that transmits 60% or more of the light emitted from the light-emitting element 20.

The lower surface of the light-transmissive member 30 preferably covers the entire upper surface of the light-emitting element 20, in order that the light emitted from the light-emitting element 20 is extracted efficiently. That is, in a plan view in the horizontal direction, an edge portion of the upper surface of the light-emitting element 20 is preferably covered so as to be surrounded by the edge portion of the lower surface of the light-transmissive member 30. Furthermore, an area of the upper surface of the light-transmissive member 30 is preferably smaller than the sum of areas of upper surfaces of the plurality of light-emitting elements 20 included in the light-emitting device 200. Thus, the emitted light that is emitted from the light-emitting element 20 and is incident on the lower surface of the light-transmissive member 30 can be emitted from the upper surface of the light-transmissive member 30 (that is, a light-emitting surface of the light-emitting device 200) having a smaller area. That is, in the light-emitting device 200, the emitted light from each of the light-emitting elements 20 is narrowed by the light-transmissive member 30, and thus, the light-emitting device 200 has a high luminance and can illuminate an area further away.

The light-transmissive member 30 can individually cover each of the plurality of light-emitting elements 20 or can integrally cover the plurality of light-emitting elements 20. An outer peripheral lateral surface of the light-transmissive member 30 is preferably covered with the reflective member 40.

The thickness of the light-transmissive member 30 is not particularly limited, but is preferably in a range from 50 μm to 300 μm.

When one light-emitting device 200 includes a plurality of light-transmissive members 30, the upper surfaces of the plurality of light-transmissive members 30 are preferably flush or substantially flush with each other. This makes it possible to more reliably prevent interference between light beams emitted from the lateral surfaces of the light-transmissive members 30. On the other hand, regardless of the number of the light-transmissive members 30, the upper surfaces thereof can have any of various shapes such as a shape including protrusions and recessions, a curved surface, and a lens shape. The lower surface of each of the light-transmissive members 30 is preferably parallel to the light-extracting surface of the light-emitting element 20.

For example, the light-transmissive member 30 can be made of a material containing a light-diffusing material or a phosphor that can convert the wavelength of at least a part of the light incident from the light-emitting element 20. Examples of the light-transmissive member 30 containing a phosphor include a sintered compact of phosphor; and a material obtained by adding a phosphor powder to a resin, glass, or other inorganic material. The sintered compact of phosphor can be made by sintering only the phosphor, or can be made by sintering a mixture of the phosphor and a sintering aid. When the mixture of the phosphor and the sintering aid is sintered, an inorganic material such as silicon oxide, aluminum oxide, or titanium oxide is preferably used as the sintering aid. Accordingly, even when the light-emitting element 20 has a high output, it is possible to suppress discoloration and deformation of the sintering aid due to light or heat. As the light transmittance of the light-transmissive member 30 is higher, the light-transmissive member 30 more easily reflects light at the interface with the reflective member 40, and thus, the luminance can be improved.

A phosphor that can be excited by the light emitted from the light-emitting element 20 is used as the phosphor contained in the light-transmissive member 30. One of the specific examples of phosphors mentioned below can be used alone, or a combination of two or more types thereof can be used. Specific examples of the phosphor that can be excited by a blue light-emitting element or an ultraviolet light-emitting element include an yttrium aluminum garnet-based phosphor activated with cerium (for example, Y₃(Al,Ga)₅O₁₂:Ce), a lutetium aluminum garnet-based phosphor activated with cerium (for example, Lu₃(Al,Ga)₅O₁₂:Ce), a nitrogen-containing calcium aluminosilicate-based phosphor activated with europium and/or chromium (for example, CaO—Al₂O₃—SiO₂:Eu), a terbium aluminum garnet-based phosphor (for example, Tb₃(Al,Ga)₅O₁₂:Ce), a silicate-based phosphor activated with europium (for example, (Sr,Ba)₂SiO₄: Eu), a β-sialon phosphor (for example, Si_{6-z}Al₂O₂N_{8-z}:Eu (0<Z<4.2)), an α-sialon phosphor (for example, Mz(Si,Al)₁₂(O,N)₁₆ (in which 0<z≤2 is satisfied, and M is Li, Mg, Ca, Y, or a lanthanide element other than La and Ce)), a nitride-based phosphor such as a CASN-based phosphor (for example, CaAlSiN₃:Eu) or an SCASN-based phosphor (for example, (Sr,Ca)AlSiN₃:Eu), a potassium fluorosilicate-based phosphor activated with manganese (for example, K₂SiF₆:Mn, K₂(Si,Al)F₆:Mn, 3.5MgO·0.5MgF₂·GeO₂:Mn), a sulfide-based phosphor, and a quantum dot phosphor (for example, perovskite and chalcopyrite). Any of these phosphors are combined with a blue light-emitting element or an ultraviolet light-emitting element, so that light-emitting devices of various colors (for example, a white-based light-emitting device) can be manufactured. When a light-emitting device is designed to emit white light, the type and the concentration of the phosphor contained in the light-transmissive member 30 are adjusted in such a manner that white light is emitted. When such a phosphor is contained in the light-transmissive member 30, the concentration of the phosphor is preferably in a range from about 5% to 50%.

The light-transmissive member 30 and the light-extracting surface of the light-emitting element 20 can be bonded together via a light guide member 61, for example. The light-transmissive member 30 and the light-emitting element 20 can be bonded together directly by using pressure bonding, sintering, surface activation bonding, atomic diffusion bonding, hydroxyl group bonding, without using the light guide member 61.

The light-transmissive member 30 is normally arranged on the upper surface of the light-emitting element 20, but can cover a part of the region 10 and/or a part of the pad portion 11, depending on the form of the light-transmissive member 30.

### Frame Body 41

The frame body 41 is arranged on the ceramic substrate 100 so as to surround the light-emitting elements 20. In a plan view in the horizontal direction, the outer edge of the frame body 41 preferably envelops the boundary between the region 10 and the pad portion 11. Thus, a step between the region 10 and the pad portion 11 is covered by the frame body 41, so that a contact area with the frame body 41 is increased and an anchor effect can be exhibited by the step.

The frame body 41 is spaced apart from the outer edge of the upper surface of the ceramic substrate 100. Accordingly, in a manufacturing process of the light-emitting device 200, the frame body 41 and the reflective member 40 are not arranged on a singulation line when an aggregate of light-emitting devices 200 is separated into individual light-emitting devices 200. That is, the resin member is not cut during singulation, and thus, it is possible to suppress a change in the shape of the resin member due to stress during cutting, to suppress peeling of the resin member from the ceramic substrate 100, and the like.

The frame body 41 is made of an insulating member so as to cover the region 10 and a part of the pad portion 11. The frame body 41 can be made by using an insulating resin member, for example. Examples of the insulating resin member include a silicone resin, a modified silicone resin, an epoxy resin, a modified epoxy resin, an acrylic resin, and a hybrid resin containing at least one type or more of these resins. These resins can be used alone or in combination of two or more types.

In the frame body 41, an insulating resin member can contain a filler such as a light reflective material. As the light reflective material, a material same as or similar to the light reflective material in the reflective member 40 can be used.

In a case in which the frame body 41 contacts the region 10, the region 10 preferably has a groove or a hole 12 on the surface of a region contacting the frame body 41. The ceramic plate 1 is preferably exposed at a bottom surface of the groove or the hole 12. Thus, the adhesion between the frame body 41 and the ceramic substrate 100 can be improved, and it is possible to obtain the light-emitting device 200 having further increased reliability.

### Other Members

A different element such as a protective element 42 and an electronic component can be mounted in the light-emitting device 200. The different element and the electronic component are preferably embedded in the reflective member 40.

The light-emitting device 200 can include a recognition mark 14 on the upper surface. The recognition mark 14 is provided between the outer edge of the frame body 41 and one side of the outer edge of the substantially rectangular ceramic substrate 100 along which the region 10 and the pad portion 11 do not extend. The recognition mark 14 can be used for position recognition of the light-emitting surface of the light-emitting device 200 when the light-emitting device 200 is secondarily mounted, position recognition when the frame body 41 is formed in the manufacturing process, and the like. For example, the recognition mark 14 can be formed by using the same metal material as in the pad portion 11. Using the same material for the recognition mark 14 and the surface of the pad portion 11 makes it possible to suppress corrosion of metal due to the potential difference between different metal materials.

### Method of Manufacturing Light-Emitting Device

A method of manufacturing a light-emitting device according to the embodiment includes preparing the ceramic substrate 100 according to the embodiment, arranging the light-emitting element 20 on the ceramic substrate 100, and arranging the reflective member 40 on the upper surface of the ceramic substrate 100. In arranging the reflective member 40, the reflective member 40 is arranged so as to contact the Au layer 5 and the seed layer 2 of the ceramic substrate 100.

FIG. 14 is a flowchart illustrating an example of a method of manufacturing a light-emitting device according to the embodiment.

### (S41) Preparing Ceramic Substrate

In step S41 in which the ceramic substrate 100 is prepared, the ceramic substrate 100 according to the embodiment is prepared.

The ceramic substrate 100 can include a plurality of regions in which the light-emitting elements 20 are arranged, and can have a size enough for singulation to separate each of the light-emitting devices 200 after the reflective member 40 is arranged, or the ceramic substrate 100 can have the dimensions for each single light-emitting device 200.

### (S42) Arranging Light-Emitting Element

In step S42 in which a light-emitting element is arranged, the light-emitting element 20 is arranged on the ceramic substrate 100. In step S42 in which the light-emitting element is arranged, an electrode of the light-emitting element 20 and the upper surface of the region 10 are preferably connected by using the bonding member 60. The light-emitting element 20 is preferably arranged in a state in which the light-transmissive member 30 is connected to the light-emitting element 20 in advance. When the light-transmissive member 30 is bonded to the light-emitting element 20, a light-transmissive bonding material is suitably used.

### (S43) Arranging Reflective Member

In step S43 in which a reflective member is arranged, the reflective member 40 is arranged on the upper surface of the ceramic substrate 100. At this time, the reflective member 40 is arranged so as to contact the Au layer 5 and the seed layer 2 of the ceramic substrate 100. Thus, lifting (stripping) of the reflective member can be suppressed. In step S43 in which the reflective member is arranged, the reflective member 40 is preferably arranged so as to cover the lateral surface of the light-emitting element 20. The reflective member 40 is arranged on the ceramic substrate 100 so as to surround the light-emitting element 20 and expose the upper surface of the light-transmissive member 30 arranged on the light-extracting surface of the light-emitting element 20. The reflective member 40 is preferably arranged so as to have a rectangular shape in a plan view.

In the method of manufacturing a light-emitting device according to the embodiment, a singulation process is performed as necessary, after step S43 in which the reflective member is arranged. For the light-emitting device 200, a single unit of the light-emitting device 200 is set in advance by the number of the light-emitting elements 20 being used. Therefore, when a plurality of the light-emitting devices 200 are manufactured together, a singulation process is performed. When the singulation process is performed, the plurality of light-emitting devices 200 are manufactured by cutting in a lattice pattern. Examples of a cutting method include methods using a rotating blade having a disk shape, an ultrasonic cutter, and a laser light irradiation blade.

### EXAMPLES

The present invention is described in detail below with reference to Example. However, the present invention is not limited to this Example.

### First Example

The ceramic substrate 100 was manufactured based on the flowchart according to the fourth embodiment illustrated in FIG. 11. After step S34 in which a Cu layer is arranged, the upper surface of an intermediate formed and a cross section of the intermediate in the thickness direction were observed by using a scanning electron microscope (SEM) under conditions including BED-C, acceleration voltage: 5.0 kV, irradiation current mode: Std.-PC 50.0, and high vacuum.

The cross-section of the intermediate in the thickness direction was exposed by cutting the intermediate in the thickness direction (Z-axis direction) by focused ion beam machining (FIB).

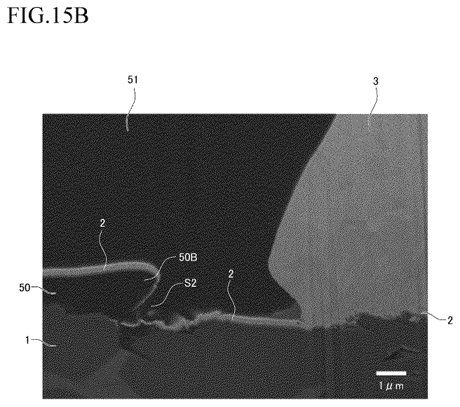

FIG. 15A is an SEM image of the intermediate of the ceramic substrate 100 in a plan view in the horizontal direction obtained in step S34 in which a Cu layer is arranged in the method of manufacturing a ceramic substrate according to the fourth embodiment, and observed from above at a magnification of 50 times. FIG. 15B is an enlarged image of a cross section of a region XVB in FIG. 15A in a thickness direction, and is an SEM image of a cross section of the intermediate of the ceramic substrate 100 obtained in step S34 in which a Cu layer is arranged in the method of manufacturing a ceramic substrate according to the fourth embodiment, and observed at a magnification of 10000 times.

From the SEM images, the ceramic plate 1, the first resist layer 50 arranged on the upper surface of the ceramic plate 1 and having an overhanging shape (an inverted tapered shape) in a cross-sectional view, the seed layer 2 arranged on the upper surface of the ceramic plate 1, on the upper surface of the first resist layer 50, and on the lateral surface of the first resist layer 50, the Cu layer arranged on the upper surface of the seed layer 2, and the space S2 between the upper surface of the ceramic plate 1 and the lower surface of the protruding portion 50B were observed. Although not clearly observed in the SEM image, a dry film of the second resist layer 51 is arranged so as to contact the lateral surface of the Cu layer 3 and the upper surface of the seed layer 2 arranged on the upper surface of the first resist layer 50.

As described above, the present invention has been described based on specific embodiments, but these are merely presented as examples, and the present invention is not limited to the above-described embodiments. The above embodiments can be embodied in various other forms, and various combinations, omissions, substitutions, additions, modifications, and the like can be made without departing from the spirit of the invention. These embodiments and variations thereof are included in the scope and spirit of the invention and are within the scope of the invention described in the claims and equivalents thereof.

1. A ceramic substrate comprising:
a ceramic plate;
a seed layer arranged on an upper surface of the ceramic plate;
a Cu layer arranged on an upper surface of the seed layer;
an intermediate layer of one or more layers arranged on an upper surface of the Cu layer and a lateral surface of the Cu layer; and
an Au layer arranged on an upper surface of the intermediate layer and a lateral surface of the intermediate layer, wherein
the upper surface of the seed layer and a lower surface of the intermediate layer contact each other,
the upper surface of the ceramic plate and a lower surface of the Au layer do not contact each other, and
an edge portion of the upper surface of the seed layer is located outside an edge portion of a lower surface of the Cu layer in a horizontal direction.

2. The ceramic substrate according to claim 1, wherein the edge portion of the upper surface of the seed layer is located inside an edge portion of the lower surface of the Au layer in the horizontal direction.

3. The ceramic substrate according to claim 1, wherein a lateral surface of the seed layer is exposed from the Au layer.

4. The ceramic substrate according to claim 1, wherein
the seed layer is continuous from the lower surface of the Cu layer to a part of the lateral surface of the Cu layer, and
the intermediate layer is arranged to cover the seed layer arranged on the part of the lateral surface of the Cu layer.

5. The ceramic substrate according to claim 1, wherein
the intermediate layer comprises a Ni layer and a Pd layer,
the Ni layer is arranged on the upper surface of the Cu layer and the lateral surface of the Cu layer,
the Pd layer is arranged on an upper surface of the Ni layer and a lateral surface of the Ni layer, and
the Au layer is arranged on an upper surface of the Pd layer and a lateral surface of the Pd layer.

6. The ceramic substrate according to claim 1, wherein the seed layer is made up of one or more types of layers selected from the group consisting of a Ti layer, a Cu layer, an Au layer, a Ru layer, a TiNi layer, a TiW layer, a CuNi layer, and a NiCr layer.

7. The ceramic substrate according to claim 1, wherein the seed layer has an average thickness in a range from 0.1 μm to 2.0 μm.

8. The ceramic substrate according to claim 1, wherein the edge portion of the upper surface of the seed layer is arranged inside in a range from 1.0 μm to 5.0 μm from the edge portion of the lower surface of the Au layer in the horizontal direction.

9. The ceramic substrate according to claim 1, further comprising a pad portion electrically connected to the Au layer.

10. The ceramic substrate according to claim 9, wherein the pad portion comprises:
the ceramic plate;
the seed layer arranged on the upper surface of the ceramic plate;
the intermediate layer arranged on the upper surface of the seed layer; and
the Au layer arranged on the upper surface of the intermediate layer.

11. The ceramic substrate according to claim 9, wherein the pad portion comprises:
the ceramic plate;
the seed layer arranged on the upper surface of the ceramic plate; and
an Al layer arranged on the upper surface of the seed layer.

12. A light-emitting device comprising:
the ceramic substrate according to claim 1; and
a light-emitting element arranged on the ceramic substrate.

13. The light-emitting device according to claim 12, further comprising a reflective member arranged on the upper surface of the ceramic substrate, wherein
the reflective member contacts the Au layer and the seed layer.

14. A method of manufacturing a ceramic substrate, the method comprising:
providing a first resist layer on an upper surface of a ceramic plate, and exposing the first resist layer to light and developing the first resist layer into a predetermined shape;
arranging a seed layer on the upper surface of the ceramic plate exposed from the first resist layer having been exposed to light and developed, on a lateral surface of the first resist layer, and on an upper surface of the first resist layer;
providing a second resist layer to cover at least a part of an upper surface of the seed layer, and exposing the second resist layer to light and developing the second resist layer into a predetermined shape, to expose at least a part of the upper surface of the seed layer arranged on the upper surface of the ceramic plate;
arranging, by electrolytic plating, a Cu layer on the upper surface of the seed layer exposed from the second resist layer having been exposed to light and developed;
removing a part of the seed layer, the first resist layer, and the second resist layer;
arranging an intermediate layer of one or more layers on an upper surface of the Cu layer and a lateral surface of the Cu layer; and
arranging an Au layer on an upper surface of the intermediate layer and a lateral surface of the intermediate layer.

15. The method of manufacturing a ceramic substrate according to claim 14, wherein
in the exposing of the first resist layer to light and developing of the first resist layer into a predetermined shape, a length of a lower surface of the first resist layer in a cross section in a thickness direction of the ceramic plate is smaller than a length of the upper surface of the first resist layer, and
in the arranging of the seed layer, the seed layer is arranged to continuously cover the lateral surface of the first resist layer and the upper surface of the ceramic plate exposed from the first resist layer.

16. The method of manufacturing a ceramic substrate according to claim 15, wherein
in the exposing of the first resist layer to light and developing of the first resist layer into a predetermined shape, the first resist layer is formed that the first resist layer has an overhanging shape in a cross-sectional view, and
in the exposing of the second resist layer to light and developing of the second resist layer into a predetermined shape, the second resist layer is a sheet resist.

17. The method of manufacturing a ceramic substrate according to claim 14, wherein in the exposing of the second resist layer to light and developing of the second resist layer into a predetermined shape, the second resist layer is exposed to light and developed not to expose the seed layer arranged on the lateral surface of the first resist layer and the upper surface of the first resist layer, and to expose at least a part of the upper surface of the seed layer arranged on the upper surface of the ceramic plate from the second resist layer.

18. The method of manufacturing a ceramic substrate according to claim 14, wherein in the arranging of the seed layer, the seed layer has a thickness in a range from 1.0 μm to 2.0 μm.

19. The method of manufacturing a ceramic substrate according to claim 14, wherein in the arranging of the intermediate layer, the intermediate layer is arranged to cover the upper surface of the seed layer arranged on the upper surface of the ceramic plate.

20. The method of manufacturing a ceramic substrate according to claim 14, wherein
the arranging of the intermediate layer comprises arranging a Ni layer on an upper surface of the Cu layer and a lateral surface of the Cu layer, and arranging a Pd layer on an upper surface of the Ni layer and a lateral surface of the Ni layer, and
in the arranging of the Au layer, the Au layer is arranged on an upper surface of the Pd layer and a lateral surface of the Pd layer.

21. The method of manufacturing a ceramic substrate according to claim 14, wherein
in the exposing of the second resist layer to light and developing of the second resist layer into a predetermined shape, the second resist layer is exposed to light and developed to expose the seed layer arranged on the lateral surface of the first resist layer, and
in the arranging of the Cu layer, the Cu layer is arranged by electrolytic plating on the seed layer arranged on the lateral surface of the first resist layer.

22. The method of manufacturing a ceramic substrate according to claim 14, wherein the arranging of the intermediate layer comprises arranging the intermediate layer to cover the upper surface of the Cu layer and the seed layer arranged on the lateral surface of the Cu layer.

23. The method of manufacturing a ceramic substrate according to claim 14, wherein after the removing of the first resist layer and the second resist layer, an edge portion of the upper surface of the seed layer is arranged outside an edge portion of a lower surface of the Cu layer in a horizontal direction.

24. The method of manufacturing a ceramic substrate according to claim 14, wherein the first resist layer and the second resist layer are made of a negative photoresist.

25. A method of manufacturing a light-emitting device, the method comprising:
preparing the ceramic substrate according to claim 1;
arranging a light-emitting element on the ceramic substrate; and
arranging a reflective member on an upper surface of the ceramic substrate, wherein
in the arranging of the reflective member, the reflective member is arranged to contact the Au layer and the seed layer of the ceramic substrate.
